(19) United States
(12) Patent Application Publication
(10) Pub. No.: US 2018/0124916 A1
(43) Pub. Date: May 3, 2018

(54) WIRING BOARD AND ELECTRONIC DEVICE USING THE WIRING BOARD

(71) Applicant: KYOCERA Corporation, Kyoto-shi (JP)

(72) Inventor: Seiji HATTORI, Otsu-shi (JP)

(73) Assignee: KYOCERA Corporation, Kyoto-shi (JP)

(21) Appl. No.: 15/662,837

(22) Filed: Jul. 28, 2017

(30) Foreign Application Priority Data
Oct. 28, 2016 (JP) 2016-211640
Oct. 28, 2016 (JP) 2016-211643
Nov. 16, 2016 (JP) 2016-223033
Nov. 17, 2016 (JP) 2016-223824
Dec. 8, 2016 (JP) 2016-238190

(51) Int. Cl. H05K 1/11; H05K 1/02; H05K 1/18

(52) U.S. Cl. CPC H05K 1/113; H05K 1/181; H05K 1/0298

(57) ABSTRACT

A wiring board according to the present disclosure includes an insulating substrate having a semiconductor-element mount portion, a constant-voltage-regulator mount portion, and an external connection surface; semiconductor-element connection pads; constant-voltage-regulator connection pads; external connection pads; and wiring conductors including a wiring conductor for signal connected to the semiconductor-element connection pad for signal in an outer peripheral portion of the insulating substrate and extending in the insulating substrate from an area below the semiconductor-element mount portion to the outer peripheral portion. The wiring conductor for signal extends on a surface of a build-up insulating layer of the insulating substrate, on which the solid conductor for grounding or for power supply extends, to the outer peripheral portion without passing through an area below an intermediate portion between the semiconductor-element mount portion and the constant-voltage-regulator mount portion.

### BACKGROUND OF THE INVENTION

### 1. Field of the Invention

The present disclosure relates to a wiring board for mounting a semiconductor element thereon, and an electronic device using the wiring board.

### 2. Description of the Related Art

In related art, a semiconductor element such as a microprocessing unit (MPU) is used while being mounted on a small wiring board with multilayer high-density wiring. The wiring board mainly includes an insulating substrate, a wiring conductor, and a solder resist layer. A semiconductor element is mounted on this wiring board, thereby forming an electronic device (Japanese Unexamined Patent Application Publication (Translation of PCT Application) No. 2007-521574).

### SUMMARY OF THE INVENTION

A wiring board according to a first aspect of the present disclosure includes an insulating substrate in which a plurality of build-up insulating layers including a plurality of via holes is stacked on upper and lower surfaces of a core insulating layer including a plurality of through holes, the insulating substrate including a semiconductor-element mount portion at a center portion of an upper surface of the insulating substrate, a constant-voltage-regulator mount portion at an outer peripheral portion of the upper surface of the insulating substrate, and an external connection surface at a lower surface of the insulating substrate; and a wiring conductor applied on the upper and lower surfaces of the core insulating layer, in the through holes, on surfaces of the build-up insulating layers, and in the via holes. The wiring conductor includes a plurality of semiconductor-element connection pads for signal, for grounding, and for power supply in the semiconductor-element mount portion; a plurality of constant-voltage-regulator connection pads for grounding and for power supply in the constant-voltage-regulator mount portion; a plurality of external connection pads for signal, for grounding, and for power supply in the external connection surface; a plurality of wiring conductors for signal connected to the semiconductor-element connection pad for signal in an area below the semiconductor-element mount portion, connected to the external connection pad for signal in an outer peripheral portion of the insulating substrate, and extending in the insulating substrate from the area below the semiconductor-element mount portion to the outer peripheral portion of the insulating substrate; a plurality of solid conductors for grounding connected to the semiconductor-element connection pad for grounding in the area below the semiconductor-element mount portion, connected to the constant-voltage-regulator connection pad for grounding in an area below the constant-voltage-regulator mount portion, connected to the external connection pad for grounding in the area below the semiconductor-element mount portion and the area below the constant-voltage-regulator mount portion, and extending on surfaces of a plurality of the build-up insulating layers at an upper-surface side and a lower-surface side of the core insulating layer from the area below the semiconductor-element mount portion to the area below the constant-voltage-regulator mount portion; and a plurality of solid conductors for power supply connected to the semiconductor-element connection pad for power supply in the area below the semiconductor-element mount portion, connected to the constant-voltage-regulator connection pad for power supply in the area below the constant-voltage-regulator mount portion, connected to the external connection pad for power supply in the area below the semiconductor-element mount portion and the area below the constant-voltage-regulator mount portion, and extending on surfaces of a plurality of the build-up insulating layers at the upper-surface side and the lower-surface side of the core insulating layer from the area below the semiconductor-element mount portion to the area below the constant-voltage-regulator mount portion. The wiring conductors for signal extend on the surface of the build-up insulating layer, on which the solid conductor for grounding or the solid conductor for power supply extends, to the outer peripheral portion of the insulating substrate without passing through an area below an intermediate portion between the semiconductor-element mount portion and the constant-voltage-regulator mount portion.

In an electronic device according to a second aspect of the present disclosure, a semiconductor element is mounted on the semiconductor-element mount portion and a constant-voltage regulator is mounted on the constant-voltage-regulator mount portion of the wiring board according to the first aspect of the present disclosure.

### BRIEF DESCRIPTION OF THE DRAWINGS

FIG. 1 is a schematic cross-sectional view illustrating a wiring board according to a first embodiment of the present disclosure;

FIG. 2 is a schematic top view illustrating a build-up conductor in the uppermost layer of the wiring board according to the first embodiment of the present disclosure;

FIG. 3 is a schematic top view illustrating a second build-up conductor from the top of the wiring board according to the first embodiment of the present disclosure;

FIG. 4 is a schematic top view illustrating a core conductor applied on the upper surface of a core insulating layer of the wiring board according to the first embodiment of the present disclosure;

FIG. 5 is a schematic top view illustrating a core conductor applied on the lower surface of the core insulating layer of the wiring board according to the first embodiment of the present disclosure;

FIG. 6 is a schematic top view illustrating a second build-up conductor from the bottom of the wiring board according to the first embodiment of the present disclosure;

FIG. 7 is a schematic top view illustrating a build-up conductor in the lowermost layer of the wiring board according to the first embodiment of the present disclosure;

FIG. 8 is a schematic cross-sectional view illustrating an electronic device according to an embodiment in which a semiconductor element and a constant-voltage regulator are mounted on the wiring board according to the first embodiment of the present disclosure;

FIG. 9 is a schematic cross-sectional view illustrating a wiring board according to a second embodiment of the present disclosure;

FIG. 10 is a schematic top view illustrating a second build-up conductor from the top of the wiring board according to the second embodiment of the present disclosure;

FIG. 11 is a schematic top view illustrating a core conductor applied on the upper surface of a core insulating layer of the wiring board according to the second embodiment of the present disclosure;

FIG. 12 is a schematic top view illustrating a core conductor applied on the lower surface of the core insulating layer of the wiring board according to the second embodiment of the present disclosure;

FIG. 13 is a schematic top view illustrating a second build-up conductor from the bottom of the wiring board according to the second embodiment of the present disclosure;

FIG. 14 is a schematic top view illustrating a build-up conductor in the lowermost layer of the wiring board according to the second embodiment of the present disclosure;

FIG. 15 is a schematic cross-sectional view illustrating an electronic device according to an embodiment in which a semiconductor element and a constant-voltage regulator are mounted on the wiring board according to the second embodiment of the present disclosure;

FIG. 16 is a schematic cross-sectional view illustrating a wiring board according to a third embodiment of the present disclosure;

FIG. 17 is a schematic top view illustrating a build-up conductor in the uppermost layer of the wiring board according to the third embodiment of the present disclosure;

FIG. 18 is a schematic top view illustrating a second build-up conductor from the top of the wiring board according to the third embodiment of the present disclosure;

FIG. 19 is a schematic top view illustrating a core conductor applied on the upper surface of a core insulating layer of the wiring board according to the third embodiment of the present disclosure;

FIG. 20 is a schematic top view illustrating a core conductor applied on the lower surface of the core insulating layer of the wiring board according to the third embodiment of the present disclosure;

FIG. 21 is a schematic top view illustrating a second build-up conductor from the bottom of the wiring board according to the third embodiment of the present disclosure;

FIG. 22 is a schematic top view illustrating a build-up conductor in the lowermost layer of the wiring board according to the third embodiment of the present disclosure;

FIG. 23 is a schematic cross-sectional view illustrating an electronic device according to an embodiment in which a semiconductor element and a constant-voltage regulator are mounted on the wiring board according to the third embodiment of the present disclosure;

FIG. 24 is a schematic cross-sectional view illustrating a wiring board according to a fourth embodiment of the present disclosure;

FIG. 25 is a schematic top view illustrating a build-up conductor in the lowermost layer of the wiring board according to the fourth embodiment of the present disclosure;

FIG. 26 is a schematic top view illustrating a second build-up conductor from the top of the wiring board according to the fourth embodiment of the present disclosure;

FIG. 27 is a schematic top view illustrating a core conductor applied on the upper surface of a core insulating layer of the wiring board according to the fourth embodiment of the present disclosure;

FIG. 28 is a schematic top view illustrating a core conductor applied on the lower surface of the core insulating layer of the wiring board according to the fourth embodiment of the present disclosure;

FIG. 29 is a schematic top view illustrating a second build-up conductor from the bottom of the wiring board according to the fourth embodiment of the present disclosure;

FIG. 30 is a schematic cross-sectional view illustrating an electronic device according to an embodiment in which a semiconductor element and a constant-voltage regulator are mounted on the wiring board according to the fourth embodiment of the present disclosure;

FIG. 31 is a schematic cross-sectional view illustrating a wiring board according to a fifth embodiment of the present disclosure;

FIG. 32 is a schematic top view illustrating a build-up conductor in the uppermost layer of the wiring board according to the fifth embodiment of the present disclosure;

FIG. 33 is a schematic top view illustrating a second build-up conductor from the top of the wiring board according to the fifth embodiment of the present disclosure;

FIG. 34 is a schematic top view illustrating a core conductor applied on the upper surface of a core insulating layer of the wiring board according to the fifth embodiment of the present disclosure;

FIG. 35 is a schematic top view illustrating a core conductor applied on the lower surface of a core insulating layer of the wiring board according to the fifth embodiment of the present disclosure;

FIG. 36 is a schematic top view illustrating a second build-up conductor from the bottom of the wiring board according to the fifth embodiment of the present disclosure;

FIG. 37 is a schematic top view illustrating a build-up conductor in the lowermost layer of the wiring board according to the fifth embodiment of the present disclosure;

FIG. 38 is a schematic cross-sectional view illustrating an electronic device according to an embodiment in which a semiconductor element and a constant-voltage regulator are mounted on the wiring board according to the fifth embodiment of the present disclosure;

FIG. 39 is a schematic top view illustrating another example of the build-up conductor in the uppermost layer illustrated in FIG. 33;

FIG. 40 is a schematic top view illustrating still another example of the build-up conductor in the uppermost layer illustrated in FIG. 33;

FIG. 41 is a schematic top view illustrating yet another example of the build-up conductor in the uppermost layer illustrated in FIG. 33; and

FIG. 42 is a schematic top view illustrating a further example of the build-up conductor in the uppermost layer illustrated in FIG. 33.

### DESCRIPTION OF THE PREFERRED EMBODIMENTS

### First Embodiment

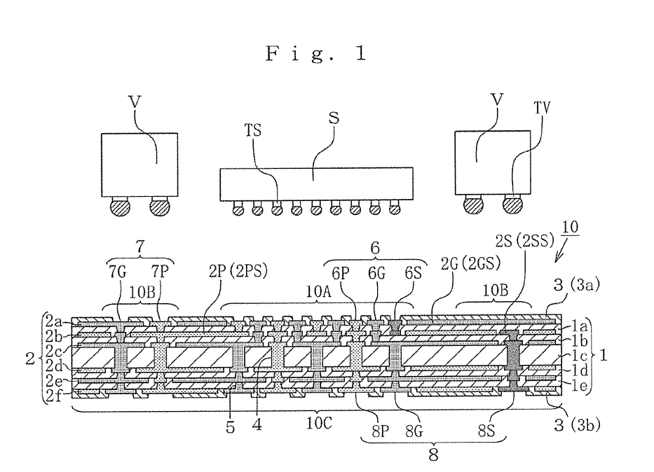

A wiring board according to a first embodiment of the present disclosure is described with reference to FIGS. 1 to 7. FIG. 1 is a schematic cross-sectional view illustrating a wiring board 10 of this example. The wiring board 10 mainly includes an insulating substrate 1, a wiring conductor 2, and a solder resist layer 3. The wiring board 10 is for mounting a semiconductor element S and a constant-voltage regulator V thereon.

The insulating substrate 1 includes a semiconductor-element mount portion 10A, on which the semiconductor element S is mounted, at a center portion of the upper surface of the insulating substrate 1. The insulating substrate 1 also includes a constant-voltage-regulator mount portion 10B, on which the constant-voltage regulator V is mounted, at an outer peripheral portion of the upper surface of the insulating substrate 1. The lower surface of the insulating substrate 1 serves as an external connection surface 10C for connection with an external electric circuit board (not illustrated) such as a mother board.

The insulating substrate 1 is formed by stacking a plurality of build-up insulating layers 1a and 1b on the upper surface of a core insulating layer 1c, and a plurality of build-up insulating layers 1d and 1e on the lower surface of the core insulating layer 1c.

The core insulating layer 1c is formed by impregnating glass woven fabric, in which, for example, glass fiber bundles are woven lengthwise and crosswise, with thermosetting resin, such as epoxy resin or bismaleimide triazine resin. The core insulating layer 1c has a thickness of about 0.1 to 1 mm. The core insulating layer 1c has multiple through holes 4 from the upper surface to the lower surface thereof. The through holes 4 each have a diameter of about 50 to 200 μm.

The build-up insulating layers 1a, 1b, 1d, and 1e are made of thermosetting resin such as epoxy resin. The build-up insulating layers 1a, 1b, 1d, and 1e each have a thickness of about 20 to 60 μm. The build-up insulating layers 1a, 1b, 1d, and 1e each have a plurality of via holes 5 from the upper surface to the lower surface of each layer. The via holes 5 each have a diameter of about 30 to 100 μm.

The wiring conductor 2 includes core conductors 2c and 2d applied on the upper and lower surfaces of the core insulating layer 1c and to the inside of the through holes 4, build-up conductors 2a, 2b, 2e, and 2f applied on the surfaces of the respective build-up insulating layers 1a, 1b, 1d, and 1e and to the inside of the via holes 5.

The core conductors 2c and 2d are made of, for example, copper foil and copper plating on the upper and lower surfaces of the core insulating layer 1c, and are made of, for example, copper plating in the through holes 4. The core conductors 2c and 2d have a thickness of about 10 to 30 μm. The core conductors 2c and 2d are formed by, for example, a known subtractive method. The inside of the through holes 4 is filled with a conductor formed simultaneously with the core conductors 2c and 2d.

The build-up conductors 2a, 2b, 2e, and 2f are made of, for example, copper plating. The build-up conductors 2a, 2b, 2e, and 2f each have a thickness of about 5 to 25 μm. The build-up conductors 2a, 2b, 2e, and 2f are made by, for example, a known semi-additive method.

A portion of the build-up conductor 2a in the uppermost layer of the wiring conductor 2 forms a semiconductor-element connection pad 6. The semiconductor-element connection pad 6 includes a semiconductor-element connection pad 6S for signal, a semiconductor-element connection pad 6G for grounding, and a semiconductor-element connection pad 6P for power supply. The semiconductor-element connection pad 6 has a circular shape with a diameter of about 50 to 100 μm. The semiconductor-element connection pad 6 is in, for example, a grid-shaped array at the semiconductor-element mount portion 10A. An electrode terminal TS of the semiconductor element S is connected to the semiconductor-element connection pad 6 via solder.

Another portion of the build-up conductor 2a in the uppermost layer of the wiring conductor 2 forms a constant-voltage-regulator connection pad 7. The constant-voltage-regulator connection pad 7 includes a constant-voltage-regulator connection pad 7G for grounding and a constant-voltage-regulator connection pad 7P for power supply. The constant-voltage-regulator connection pad 7 has a rectangular shape with a length of a side of about 50 to 500 μm, or a circular shape with a diameter of about 50 to 500 μm. An electrode terminal TV of the constant-voltage regulator V is connected to the constant-voltage-regulator connection pad 7 via solder.

A portion of the build-up conductor 2f in the lowermost layer of the wiring conductor 2 forms an external connection pad 8. The external connection pad 8 includes an external connection pad 8S for signal, an external connection pad 8G for grounding, and an external connection pad 8P for power supply. The external connection pad 8 has a circular shape with a diameter of about 250 to 1000 μm. The external connection pad 8 is in, for example, a grid-shaped array at the external connection surface 10C, in the region including the area below the semiconductor-element mount portion 10A and the area below the constant-voltage-regulator mount portion 10B. The external connection pad 8 is connected to a wiring conductor of the external electric circuit board (not illustrated) such as the mother board via solder.

The solder resist layer 3 is made of thermosetting resin such as acrylic modified epoxy resin. The solder resist layer 3 includes an upper-surface-side solder resist layer 3a on the build-up insulating layer 1a in the uppermost layer and on the build-up conductor 2a in the uppermost layer, and a lower-surface-side solder resist layer 3b on the build-up insulating layer 1e in the lowermost layer and on the build-up conductor 2f in the lowermost layer.

The upper-surface-side solder resist layer 3a has an opening that allows the semiconductor-element connection pad 6 to be exposed, and an opening that allows the constant-voltage-regulator connection pad 7 to be exposed. The lower-surface-side solder resist layer 3b has an opening that allows the external connection pad 8 to be exposed. The solder resist layer 3 is formed by applying photosensitive thermosetting resin paste on the build-up insulating layer 1a in the uppermost layer, on the build-up conductor 2a in the uppermost layer, on the build-up insulating layer 1e in the lowermost layer, and on the build-up conductor 2f in the lowermost layer by printing, exposing the applied paste to light and developing the paste using a photolithography technology, and thermally hardening the applied paste.

Predetermined portions of the semiconductor-element connection pad 6, the constant-voltage-regulator connection pad 7, and the external connection pad 8 are connected to one another via the wiring conductor 2 on the surfaces and inside of the insulating substrate 1.

The wiring conductor 2 includes a wiring conductor 2S for signal, a wiring conductor 2G for grounding, and a wiring conductor 2P for power supply.

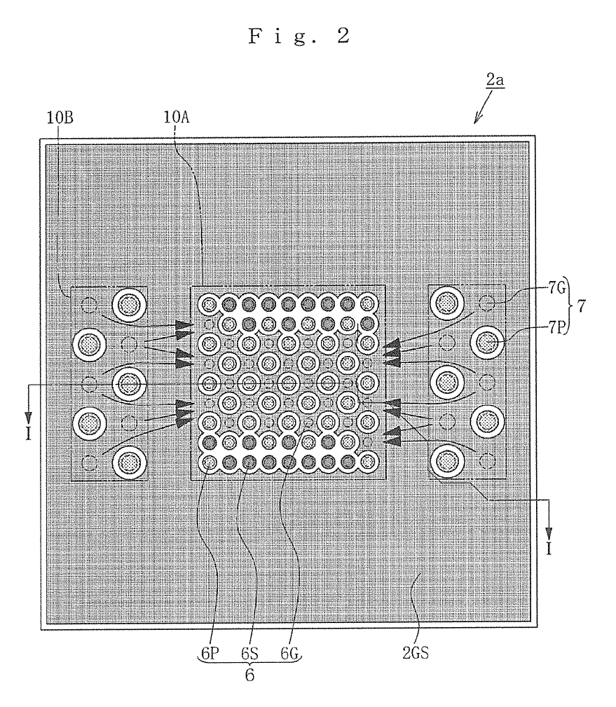

FIG. 2 illustrates the upper surface of the build-up conductor 2a applied on the surface of the build-up insulating layer 1a in the uppermost layer. In FIG. 2, regions corresponding to the semiconductor-element mount portion 10A and the constant-voltage-regulator mount portion 10B are indicated by two-dot chain lines. FIG. 1 described above illustrates a cross section taken along line I-I in FIG. 2. The openings in the solder resist layer 3a are indicated by broken lines. The semiconductor-element mount portion 10A is at a center portion of the upper surface of the insulating substrate 1. The constant-voltage-regulator mount portion 10B is at each of both sides with the semiconductor-element mount portion 10A interposed therebetween.

The build-up conductor 2a includes a plurality of the semiconductor-element connection pads 6 in the region corresponding to the mount portion 10A. The semiconductor-element connection pads 6 include a semiconductor-element connection pad 6S for signal, a semiconductor-element connection pad 6G for grounding, and a semiconductor-element connection pad 6P for power supply. Multiple semiconductor-element connection pads 6S for signal are mainly at positions corresponding to outer peripheral portions along two sides of the region corresponding to the semiconductor-element mount portion 10A, the two sides not being adjacent to regions corresponding to the constant-voltage-regulator mount portion 10B. Multiple semiconductor-element connection pads 6G for grounding and 6P for power supply are mainly at positions corresponding to the center portion of the semiconductor element mount portion 10A.

The build-up conductor 2a includes a plurality of the constant-voltage-regulator connection pads 7 in the region corresponding to the constant-voltage-regulator mount portion 10B. The constant-voltage-regulator connection pads 7 include a constant-voltage-regulator connection pad 7G for grounding and a constant-voltage-regulator connection pad 7P for power supply. The constant-voltage-regulator connection pad 7G for grounding and the constant-voltage-regulator connection pad 7P for power supply are disposed in plural arrays to be mutually alternately positioned.

The build-up conductor 2a includes a solid conductor 2GS for grounding from the region corresponding to the semiconductor-element mount portion 10A to the region corresponding to the constant-voltage-regulator mount portion 10B. The solid conductor 2GS for grounding in the build-up conductor 2a integrally contains the semiconductor-element connection pads 6G for grounding and the constant-voltage-regulator connection pads 7G for grounding. The solid conductor 2GS for grounding is connected to the external connection pad 8G for grounding via the through hole 4 and the via hole 5 in the area below the semiconductor-element mount portion 10A and the area below the constant-voltage-regulator mount portion 10B. Current for applying a grounding potential to the semiconductor element S via the solid conductor 2GS is supplied between the constant-voltage-regulator mount portion 10B and the semiconductor-element mount portion 10A.

The build-up conductor 2a does not block the current supply between the region corresponding to the semiconductor-element mount portion 10A and the region corresponding to the constant-voltage-regulator mount portion 10B. Hence, the current for applying the grounding potential to the semiconductor element S via the solid conductor 2GS for grounding in the build-up conductor 2a can be properly supplied from the constant-voltage regulator V.

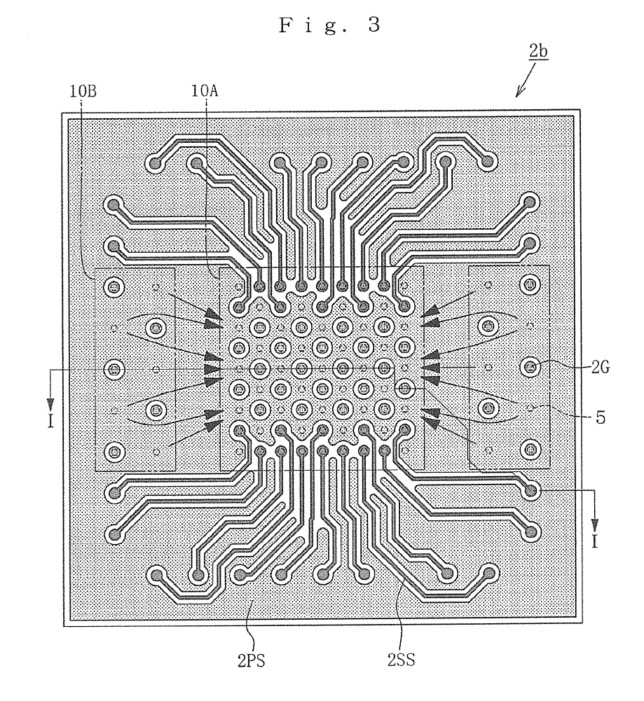

FIG. 3 illustrates the upper surface of the build-up conductor 2b applied on the surface of the second build-up insulating layer 1b from the top. In FIG. 3, regions corresponding to the semiconductor-element mount portion 10A and the constant-voltage-regulator mount portion 10B are indicated by two-dot chain lines. The positions of the via holes 5 connected from the build-up conductor 2a in the upper layer are indicated by broken lines.

The build-up conductor 2b mainly includes a strip-shaped conductor 2SS for signal and a solid conductor 2PS for power supply. Only circular land conductors for connection with the upper and lower build-up conductors 2a and 2c are formed as the wiring conductor 2G for grounding.

The strip-shaped conductor 2SS for signal in the build-up conductor 2b is a narrow strip-shaped conductor with a width of about 5 to 30 μm. The strip-shaped conductor 2SS for signal extends from the area below the semiconductor-element mount portion 10A to the outer peripheral portion of the insulating substrate 1. The strip-shaped conductor 2SS for signal extends to the outer peripheral portion of the insulating substrate 1 without passing through the area below an intermediate portion between the semiconductor-element mount portion 10A and the constant-voltage-regulator mount portion 10B. The strip-shaped conductor 2SS for signal is connected to the semiconductor-element connection pad 6S for signal in the area below the semiconductor element mount portion 10A. Also, the strip-shaped conductor 2SS for signal is connected to the external connection pad 8S for signal in the outer peripheral portion of the insulating substrate 1.

The solid conductor 2PS for power supply in the build-up conductor 2b extends from the area below the semiconductor-element mount portion 10A to the area below the constant-voltage-regulator mount portion 10B. The solid conductor 2PS for power supply is electrically connected to the semiconductor-element connection pad 6P for power supply via the via hole 5 in the upper layer, in the area below the semiconductor-element mount portion 10A. The solid conductor 2PS for power supply is also electrically connected to the constant-voltage-regulator connection pad 7P for power supply via the via hole 5 in the area below the constant-voltage-regulator mount portion 10B. The solid conductor 2PS for power supply is further connected to the external connection pad 8P for power supply via the through hole 4 and the via hole 5 in the area below the semiconductor-element mount portion 10A and the area below the constant-voltage-regulator mount portion 10B. Current for applying a power supply potential to the semiconductor element S via the solid conductor 2PS is supplied between the constant-voltage-regulator mount portion 10B and the semiconductor-element mount portion 10A.

The strip-shaped conductor 2SS for signal is in the build-up conductor 2b. The strip-shaped conductor 2SS for signal extends from the area below the semiconductor-element mount portion 10A to the outer peripheral portion of the insulating substrate 1. The strip-shaped conductor 2SS for signal extends to the outer peripheral portion of the insulating substrate 1 without passing through the area below the intermediate portion between the semiconductor-element mount portion 10A and the constant-voltage-regulator mount portion 10B. Hence, the strip-shaped conductor 2SS for signal does not significantly block current supply from the area below the semiconductor-element mount portion 10A to the area below the constant-voltage-regulator mount portion 10B. Accordingly, the current for applying the power supply potential to the semiconductor element S via the solid conductor 2PS for power supply in the build-up conductor 2b can be properly supplied from the constant-voltage regulator V.

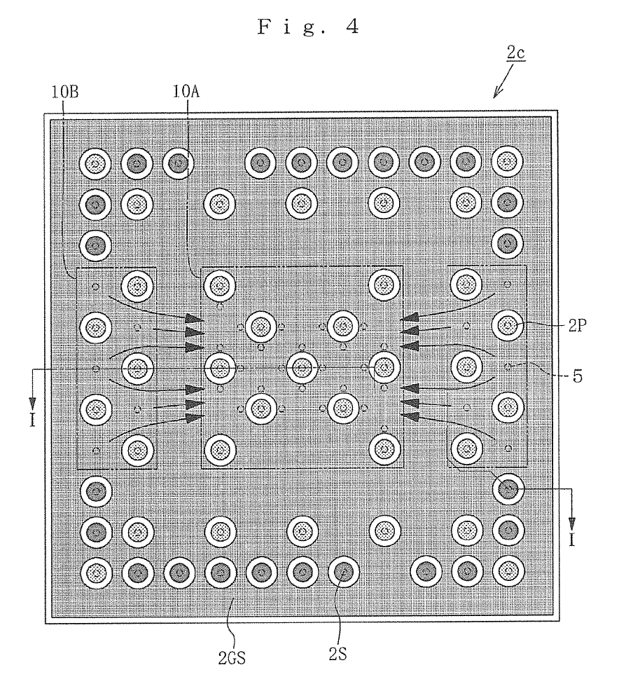

FIG. 4 illustrates the upper surface of the core conductor 2c applied on the upper surface of the core insulating layer 1c. In FIG. 4, regions corresponding to the semiconductor-element mount portion 10A and the constant-voltage-regulator mount portion 10B are indicated by two-dot chain lines. The positions of the via holes 5 connected from the build-up conductor 2b in the upper layer are indicated by broken lines.

The core conductor 2c mainly includes the solid conductor 2GS for grounding. Only circular land conductors for connection with the upper and lower build-up conductors 2b and 2d are formed as the wiring conductor 2S for signal and the wiring conductor 2P for power supply.

The solid conductor 2GS for grounding in the core conductor 2c extends from the area below the semiconductor-element mount portion 10A to the area below the constant-voltage-regulator mount portion 10B. The solid conductor 2GS for grounding is connected to the semiconductor-element connection pad 6G for grounding in the area below the semiconductor element mount portion 10A. The solid conductor 2GS for grounding is also connected to the constant-voltage-regulator connection pad 7G for grounding in the area below the constant-voltage-regulator mount portion 10B. The solid conductor 2GS for grounding is further connected to the external connection pad 8G for grounding in the area below the semiconductor-element mount portion 10A and the area below the constant-voltage-regulator mount portion 10B. Current for applying a grounding potential to the semiconductor element S via the solid conductor 2GS is supplied between the constant-voltage-regulator mount portion 10B and the semiconductor-element mount portion 10A.

The core conductor 2c does not block current supply between the area below the semiconductor-element mount portion 10A and the area below the constant-voltage-regulator mount portion 10B. Hence, the current for applying the grounding potential to the semiconductor element S via the solid conductor 2GS for grounding in the core conductor 2c can be properly supplied from the constant-voltage regulator V.

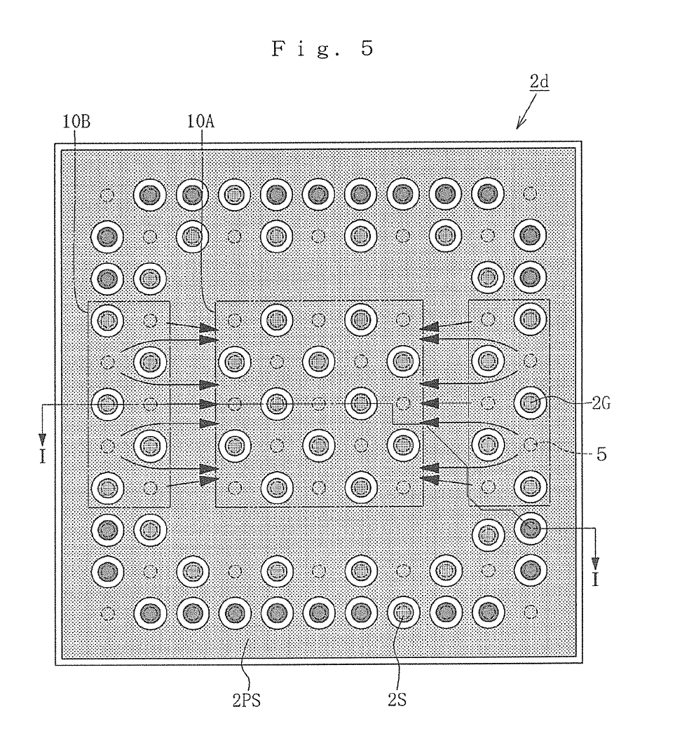

FIG. 5 illustrates the upper surface of the core conductor 2d applied on the lower surface of the core insulating layer 1c. In FIG. 5, regions corresponding to the semiconductor-element mount portion 10A and the constant-voltage-regulator mount portion 10B are indicated by two-dot chain lines. The positions of the through holes 4 connected from the core conductor 2c in the upper layer are indicated by broken lines.

The core conductor 2d mainly includes the solid conductor 2PS for power supply. Only circular land conductors for connection with the upper and lower conductors 2c and 2e are formed as the wiring conductor 2S for signal and the wiring conductor 2G for grounding.

The solid conductor 2PS for power supply in the core conductor 2d extends from the area below the semiconductor-element mount portion 10A to the area below the constant-voltage-regulator mount portion 10B. The solid conductor 2PS for power supply is connected to the semiconductor-element connection pad 6P for power supply in the area below the semiconductor element mount portion 10A. The solid conductor 2PS for power supply is connected to the constant-voltage-regulator connection pad 7P for power supply in the area below the constant-voltage-regulator mount portion 10B. The solid conductor 2PS for power supply is further connected to the external connection pad 8P for power supply in the area below the semiconductor-element mount portion 10A and the area below the constant-voltage-regulator mount portion 10B. Current for applying the power supply potential to the semiconductor element S via the solid conductor 2PS for power supply is supplied between the constant-voltage-regulator mount portion 10B and the semiconductor-element mount portion 10A.

The core conductor 2d does not block current supply between the area below the semiconductor-element mount portion 10A and the area below the constant-voltage-regulator mount portion 10B. Accordingly, the current for applying the power supply potential to the semiconductor element S via the solid conductor 2PS for power supply in the core conductor 2d can be properly supplied from the constant-voltage regulator V.

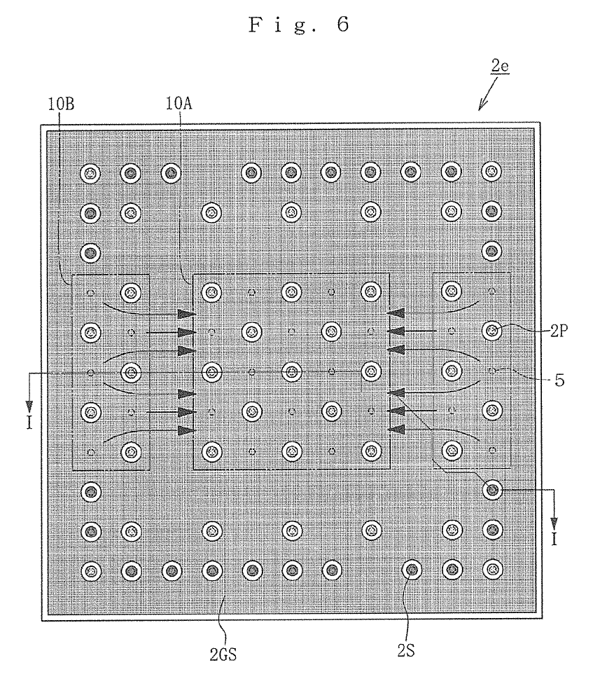

FIG. 6 illustrates the upper surface of the build-up conductor 2e applied on the surface of the second build-up insulating layer 1d from the bottom. In FIG. 6, regions corresponding to the semiconductor-element mount portion 10A and the constant-voltage-regulator mount portion 10B are indicated by two-dot chain lines. The positions of the via holes 5 connected from the core conductor 2d in the upper layer are indicated by broken lines.

The build-up conductor 2e mainly includes the solid conductor 2GS for grounding. Only circular land conductors for connection with the upper and lower conductors 2d and 2f are formed as the wiring conductor 2S for signal and the wiring conductor 2P for power supply.

The solid conductor 2GS for grounding in the build-up conductor 2e extends from the area below the semiconductor-element mount portion 10A to the area below the constant-voltage-regulator mount portion 10B. The solid conductor 2GS for grounding is connected to the semiconductor-element connection pad 6G for grounding in the area below the semiconductor element mount portion 10A. The solid conductor 2GS for grounding is also connected to the constant-voltage-regulator connection pad 7G for grounding in the area below the constant-voltage-regulator mount portion 10B. The solid conductor 2GS for grounding is further connected to the external connection pad 8G for grounding in the area below the semiconductor-element mount portion 10A and the area below the constant-voltage-regulator mount portion 10B. Current for applying the grounding potential to the semiconductor element S via the solid conductor 2GS for grounding is supplied between the constant-voltage-regulator mount portion 10B and the semiconductor-element mount portion 10A.

The build-up conductor 2e does not block current supply between the area below the semiconductor-element mount portion 10A and the area below the constant-voltage-regulator mount portion 10B. Hence, the current for applying the grounding potential to the semiconductor element S via the solid conductor 2GS for grounding in the build-up conductor 2e can be properly supplied from the constant-voltage regulator V.

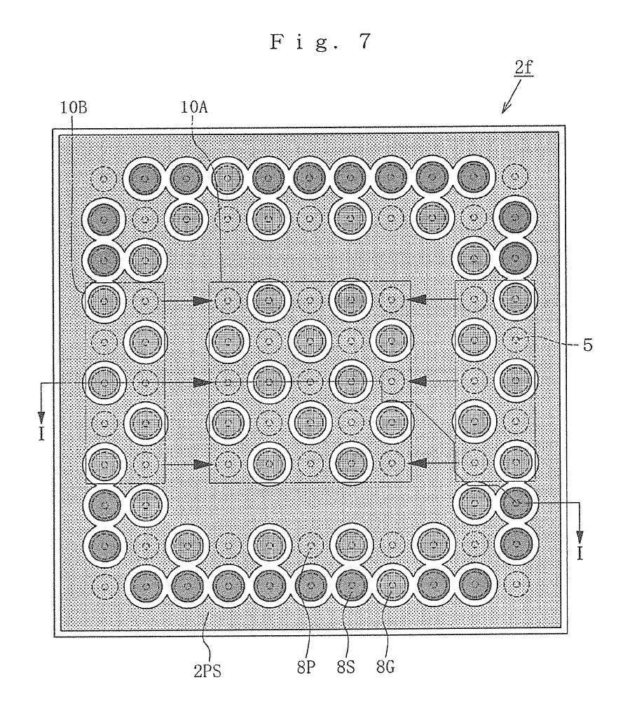

FIG. 7 illustrates the upper surface of the build-up conductor 2f applied on the surface of the build-up insulating layer 1e in the lowermost layer. In FIG. 7, regions corresponding to the semiconductor-element mount portion 10A and the constant-voltage-regulator mount portion 10B are indicated by two-dot chain lines. Also, the positions of the via holes 5 connected from the build-up conductor 2e in the upper layer and the position of the opening in the solder resist layer 3b at the lower-surface side are indicated by broken lines.

The build-up conductor 2f mainly includes the solid conductor 2PS for power supply and the external connection pads 8S for signal, 8G for grounding, and 8P for power supply. The external connection pad 8S for signal is electrically connected to the strip-shaped conductor 2SS for signal via the through hole 4 and the via hole 5. The external connection pads 8G for grounding and 8P for power supply are electrically connected to the solid conductors 2GS for grounding and 2PS for power supply via the through hole 4 and the via hole 5.

The solid conductor 2PS for power supply in this layer is integrally formed with the external connection pad 8P for power supply, and extends from the area below the semiconductor-element mount portion 10A to the area below the constant-voltage-regulator mount portion 10B. Current for applying the power supply potential to the semiconductor element S via the solid conductor 2PS for power supply is supplied between the constant-voltage-regulator mount portion 10B and the semiconductor-element mount portion 10A.

The build-up conductor 2f does not block current supply between the area below the semiconductor-element mount portion 10A and the area below the constant-voltage-regulator mount portion 10B. Accordingly, the current for applying the grounding potential to the semiconductor element S via the solid conductor 2PS for power supply in the build-up conductor 2f can be properly supplied from the constant-voltage regulator V.

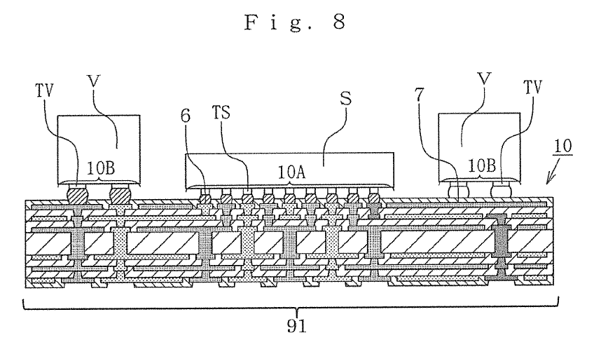

With the wiring board 10 in this embodiment, as illustrated in FIG. 8, the electrode terminal TS of the semiconductor element S is connected to the semiconductor-element connection pad 6 via solder, and the electrode terminal TV of the constant-voltage regulator V is connected to the constant-voltage-regulator connection pad 7 via solder. Accordingly, an electronic device 91 in which the semiconductor element S and the constant-voltage regulator V are mounted on the wiring board 10 is completed.

The external connection pad 8 is connected to the wiring conductor of the external electric circuit board (not illustrated) such as the mother board via solder and the electronic device 91 is mounted on the external electric circuit board.

The electronic device mounted on the external electric circuit board transmits and receives signals to and from the external electric circuit board via the external connection pad 8S for signal. The electronic device 91 is supplied with the grounding potential and the power supply potential respectively via the external connection pad 8G for grounding and the external connection pad 8P for power supply.

The electronic device 91 is also supplied with current for restricting a variation in operating voltage of the semiconductor element S from the constant-voltage regulator V via the solid conductor 2GS for grounding and the solid conductor 2PS for power supply.

With the wiring board 10 in this embodiment and the electronic device 91 using the wiring board 10, the wiring conductor 2S for signal extends on the surface of the build-up insulating layer 1b, on which the solid conductor 2PS for power supply extends, to the outer peripheral portion of the insulating substrate 1 without passing through the area below the intermediate portion between the semiconductor-element mount portion 10A and the constant-voltage-regulator mount portion 10B. Hence, the current path of the solid conductor 2PS for power supply on the surface of the build-up insulating layer 1b from the area directly below the constant-voltage-regulator mount portion 10B to the area directly below the semiconductor-element mount portion 10A is not blocked by the wiring conductor 2S for signal. Current can be sufficiently supplied to the semiconductor element S via the solid conductors 2GS for grounding and 2PS for power supply in the respective build-up conductors 2a to 2f. Accordingly, the wiring board 10 that allows the semiconductor element S to stably operate and the electronic device 91 using the wiring board 10 can be provided.

### Second Embodiment

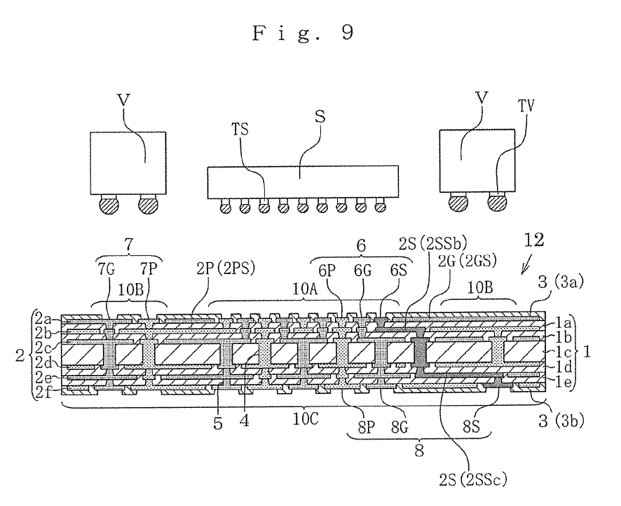

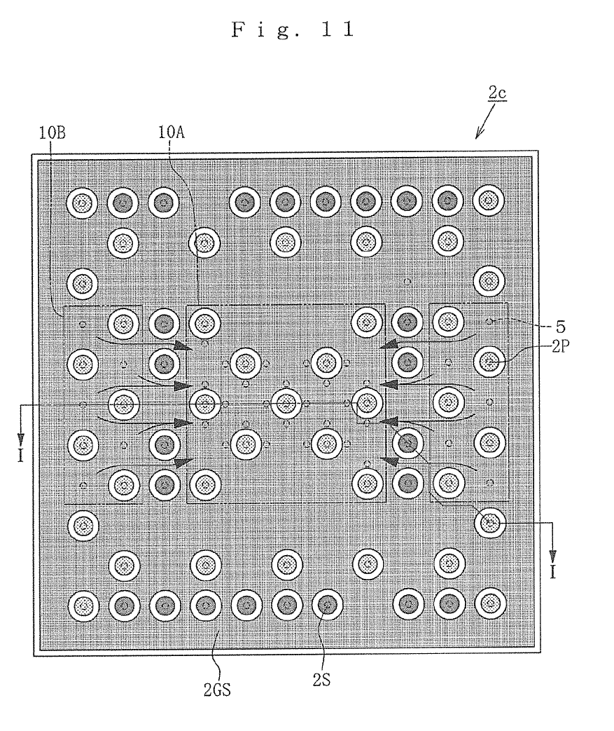

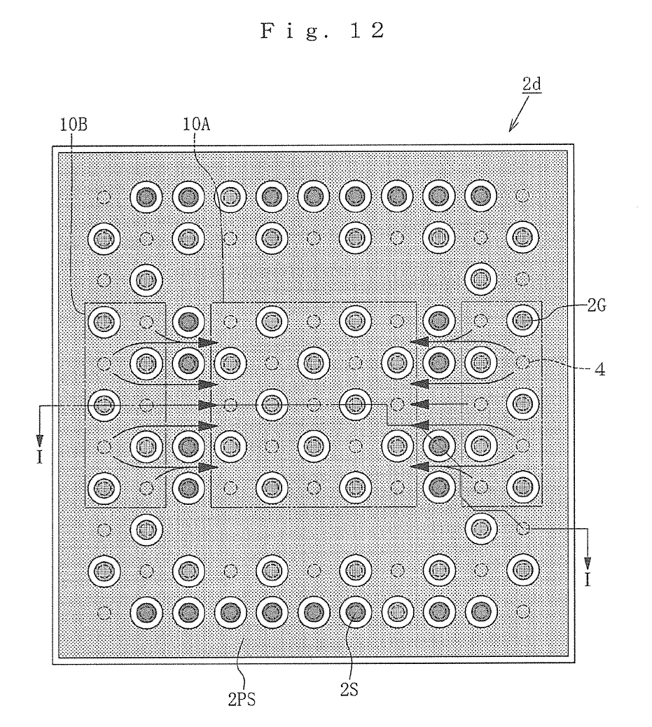

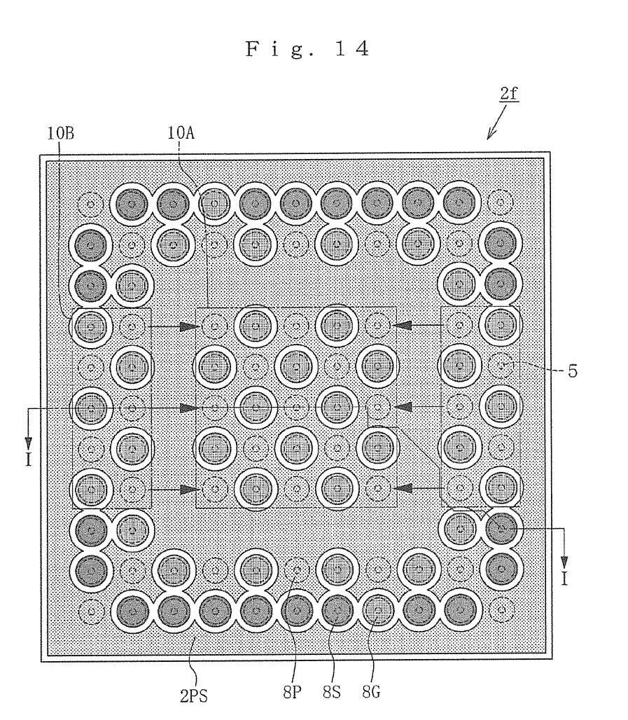

A wiring board according to a second embodiment of the present disclosure is described with reference to FIGS. 9 to 14. The same reference numerals as those of the first embodiment are applied to the same members as those of the first embodiment, and the redundant description is omitted. The description on the drawings for the same configurations as those of the above-described embodiment is also omitted.

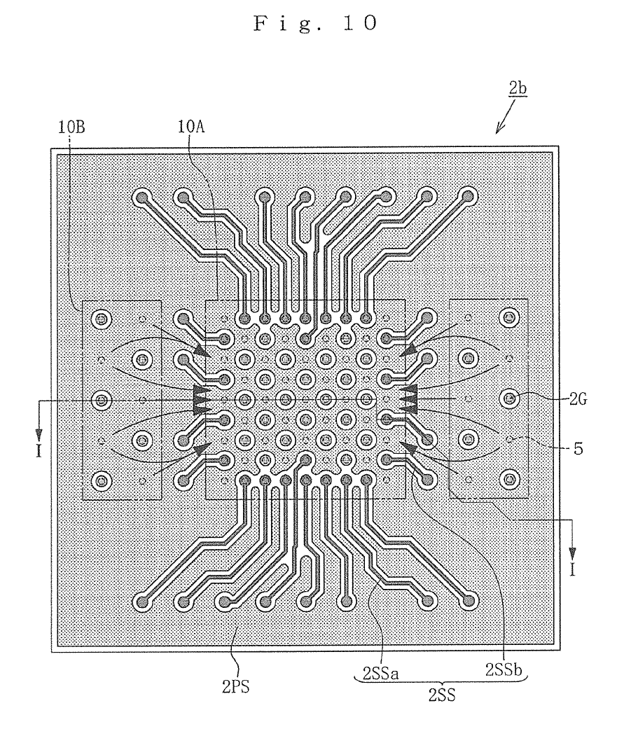

As illustrated in FIGS. 9 and 10, in a wiring board 12 according to the second embodiment of the present disclosure, the strip-shaped conductor 2SS for signal in the build-up conductor 2b is a narrow strip-shaped conductor with a width of about 5 to 30 μm. The strip-shaped conductor 2SS includes a strip-shaped conductor 2SSa extending from the area below the semiconductor-element mount portion 10A to the outer peripheral portion of the insulating substrate 1; and a strip-shaped conductor 2SSb extending only from the area below the semiconductor-element mount portion 10A to the area below the intermediate portion between the semiconductor-element mount portion 10A and the constant-voltage-regulator mount portion 10B. The strip-shaped conductor 2SS for signal is electrically connected to the semiconductor-element connection pad 6S for signal via the via holes 5 in the upper layer in the area below the semiconductor-element mount portion 10A.

In the build-up conductor 2b, the strip-shaped conductor 2SSb for signal extending from the area below the semiconductor-element mount portion 10A to the area below the intermediate portion between the semiconductor-element mount portion 10A and the constant-voltage-regulator mount portion 10B is formed; however, the strip-shaped conductor 2SS for signal extending from the area below the intermediate portion between the semiconductor-element mount portion 10A and the constant-voltage-regulator mount portion 10B to the outer peripheral portion of the insulating substrate 1 is not formed. Hence, nothing significantly blocks current supply from the area below the semiconductor-element mount portion 10A to the area below the constant-voltage-regulator mount portion 10B. Accordingly, the current for applying the power supply potential to the semiconductor element S via the solid conductor 2PS for power supply in the build-up conductor 2b can be properly supplied from the constant-voltage regulator V.

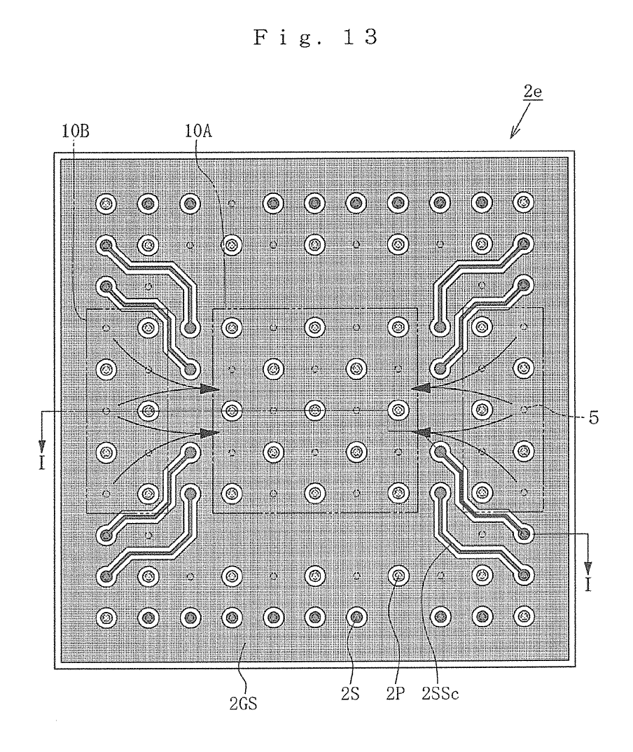

As illustrated in FIG. 13, the build-up conductor 2e mainly includes a strip-shaped conductor 2SSc for signal and the solid conductor 2GS for grounding. Only circular land conductors for connection with the upper and lower conductors 2d and 2f are formed as the wiring conductor 2P for power supply.

The strip-shaped conductor 2SSc for signal in the build-up conductor 2e is a narrow strip-shaped conductor with a width of about 5 to 30 μm. The strip-shaped conductor 2SSc extends from the area below the intermediate portion between the semiconductor-element mount portion 10A and the constant-voltage-regulator mount portion 10B to the outer peripheral portion of the wiring board 12. The strip-shaped conductor 2SSc is electrically connected to the strip-shaped conductor 2SSb of the build-up conductor 2b via the through holes 4 for signal in the area below the intermediate portion between the semiconductor-element mount portion 10A and the constant-voltage-regulator mount portion 10B. The strip-shaped conductor 2SSc is also connected to the external connection pad 8S for signal in the outer peripheral portion of the insulating substrate 1.

The strip-shaped conductor 2SSc for signal is in the build-up conductor 2e. The strip-shaped conductor 2SS for signal extends from the area below the intermediate portion between the semiconductor-element mount portion 10A and the constant-voltage-regulator mount portion 10B to the outer peripheral portion of the insulating substrate 1. Hence, the strip-shaped conductor 2SSc for signal blocks proper current supply from the area below the semiconductor-element mount portion 10A to the area below the constant-voltage-regulator mount portion 10B in this layer. However, since current for applying the grounding potential to the semiconductor element S is properly supplied via the other solid conductors 2GS on the upper surface of the core insulating layer 1c and the surface of the build-up insulating layer 1a in the uppermost layer, even if the power supply in this layer is blocked, sufficient current can be supplied.

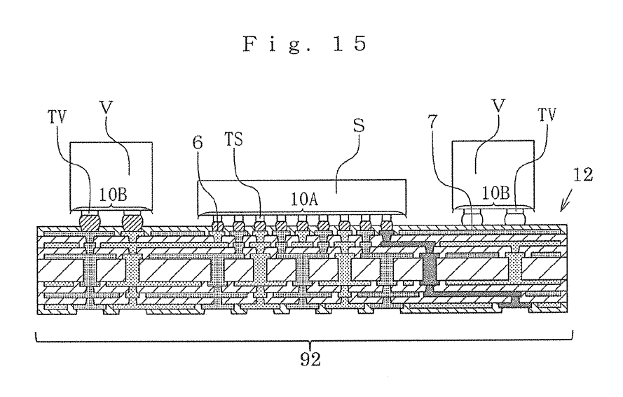

With the wiring board 12 in this embodiment, as illustrated in FIG. 15, the electrode terminal TS of the semiconductor element S is connected to the semiconductor-element connection pad 6 via solder, and the electrode terminal TV of the constant-voltage regulator V is connected to the constant-voltage-regulator connection pad 7 via solder. Accordingly, an electronic device 92 in which the semiconductor element S and the constant-voltage regulator V are mounted on the wiring board 12 is completed.

With the wiring board 12 in this embodiment and the electronic device 92 using the wiring board 12, the wiring conductor 2S for signal extending from the area below the semiconductor-element mount portion 10A via the area below the intermediate portion between the semiconductor-element mount portion 10A and the constant-voltage-regulator mount portion 10B to the outer peripheral portion of the insulating substrate 1 includes the upper-surface-side strip-shaped conductor 2SSb extending on the surface of the build-up insulating layer 1b, on which the upper-surface-side solid conductor 2PS for power supply at the upper-surface side of the core insulating layer 1c extends, from the area below the semiconductor-element mount portion 10A to the area below the intermediate portion between the semiconductor-element mount portion 10A and the constant-voltage-regulator mount portion 10B; and the lower-surface-side strip-shaped conductor 2SSc extending on the surface of the build-up insulating layer 1d, on which the solid conductor 2GS for grounding at the lower-surface side of the core insulating layer 1c extends, from the area below the intermediate portion between the semiconductor-element mount portion 10A and the constant-voltage-regulator mount portion 10B to the outer peripheral portion of the insulating substrate 1. The upper-surface-side strip-shaped conductor 2SSb is electrically connected to the lower-surface-side strip-shaped conductor 2SSc via the through hole 4 in the area below the intermediate portion between the semiconductor-element mount portion 10A and the constant-voltage-regulator mount portion 10B. Hence, the current path of the solid conductor 2PS for power supply on the surface of the build-up insulating layer 1b provided with the upper-surface-side strip-shaped conductor 2SSb from the area directly below the constant-voltage-regulator mount portion 10B to the area directly below the semiconductor-element mount portion 10A is not significantly blocked by the upper-surface-side strip-shaped conductor 2SSb. Current can be sufficiently supplied to the semiconductor element S via the solid conductor 2GS for grounding or 2PS for power supply at the upper-surface side of the core insulating layer 1c near the semiconductor-element mount portion 10A and the constant-voltage-regulator mount portion 10B. Accordingly, the wiring board 12 that allows the semiconductor element S to stable operate and the electronic device 92 using the wiring board 12 can be provided.

### Third Embodiment

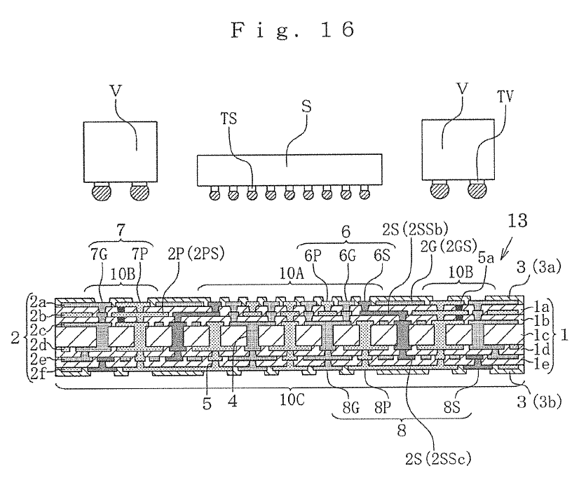

A wiring board according to a third embodiment of the present disclosure is described with reference to FIGS. 16 to 23. The same reference numerals as those of the first embodiment are applied to the same members as those of the first embodiment, and the redundant description is omitted. The description on the drawings for the same configurations as those of the above-described embodiment is also omitted.

FIG. 16 is a schematic cross-sectional view illustrating a wiring board 13 of this example. A portion of the build-up conductor 2a in the uppermost layer of the wiring conductor 2 forms the semiconductor-element connection pad 6, and another portion of the build-up conductor 2a forms the constant-voltage-regulator connection pad 7. A portion of the build-up conductor 2f in the lowermost layer of the wiring conductor 2 forms the external connection pad 8. Predetermined portions of the semiconductor-element connection pad 6, the constant-voltage-regulator connection pad 7, and the external connection pad 8 are electrically connected to one another in a thermally conductive manner via the wiring conductor 2 on the surfaces and inside of the insulating substrate 1. That is, the constant-voltage-regulator connection pad 7 (the constant-voltage-regulator connection pads 7G for grounding, 7P for power supply) is electrically connected in a thermally conductive manner to the wiring conductor 2 at the upper-surface side of the core insulating layer 1c (the solid conductor 2GS for grounding, 2PS for power supply), via a plurality of via holes 5 in the build-up conductor 2c at the upper-surface side, in the area below a plurality of constant-voltage-regulator connection pads 7 and the area below spaces between the constant-voltage-regulator connection pads 7. The solid conductors 2GS for grounding and 2PS for power supply at the upper-surface side of the core insulating layer 1c are electrically connected in a thermally conductive manner to the external connection pads 8G for grounding and 8P for power supply at the lower-surface side of the core insulating layer 1c via the through holes 4 in the core insulating layer 1c in the area below the semiconductor-element mount portion 10A, and a plurality of sub-via holes 5a in the respective lower-side build-up conductors 2e and 2f at the lower-surface side.

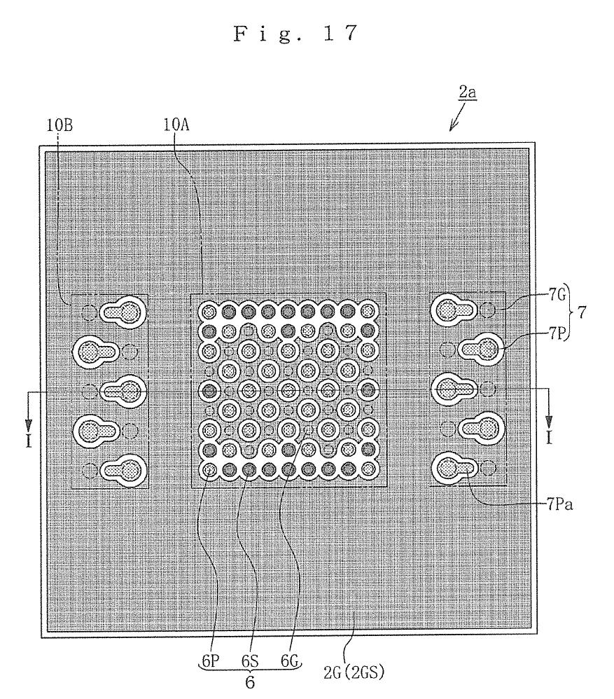

As illustrated in FIG. 17, the build-up conductor 2a includes a plurality of the constant-voltage-regulator connection pads 7 in the region corresponding to the constant-voltage-regulator mount portion 10B. The constant-voltage-regulator connection pads 7 include a constant-voltage-regulator connection pad 7G for grounding and a constant-voltage-regulator connection pad 7P for power supply. The constant-voltage-regulator connection pads 7G for grounding and the constant-voltage-regulator connection pad 7P for power supply are disposed in plural arrays to be mutually alternately positioned. Each constant-voltage-regulator connection pad 7P for power supply has a tongue piece 7Pa extending toward a center portion of the constant-voltage-regulator mount portion 10B.

The solid conductor 2GS for grounding in the build-up conductor 2a integrally contains the semiconductor-element connection pad 6G for grounding and the constant-voltage-regulator connection pad 7G for grounding. The solid conductor 2GS for grounding is electrically connected in a thermally conductive manner to the external connection pad 8G for grounding via the through holes 4 and the via holes 5 in the area below the semiconductor-element mount portion 10A and the outer peripheral portion of the insulating substrate 1.

Heat generated by the constant-voltage regulator V during operation is transferred to the solid conductor 2GS for grounding in the build-up conductor 2a via the constant-voltage-regulator connection pad 7G for grounding. This heat is transferred to the external connection pad 8G for grounding via the through holes 4 and the via holes 5 in the area below the semiconductor-element mount portion 10A and the outer peripheral portion of the insulating substrate 1, and is finally released to the outside via the external electric circuit board.

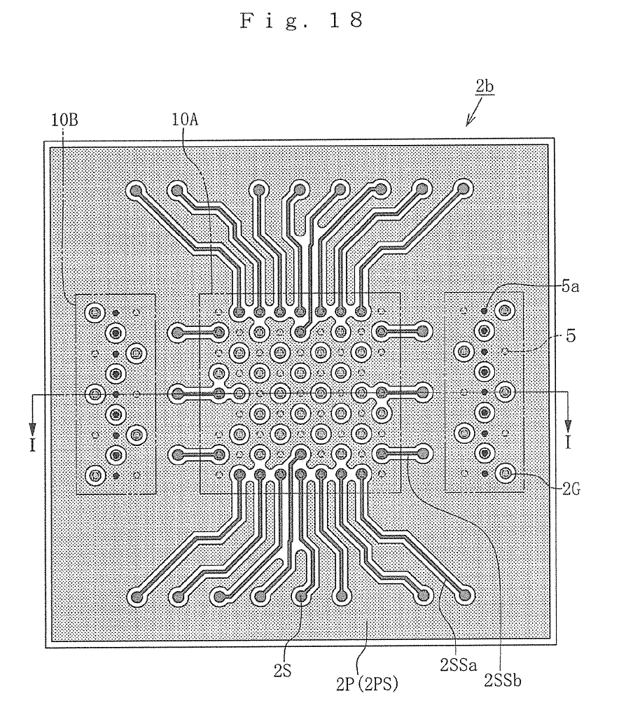

FIG. 18 illustrates the upper surface of the second build-up conductor 2b from the top. In FIG. 18, the positions of the via holes 5 connected from the build-up conductor 2a in the upper layer are indicated by broken lines. The positions of sub-via holes 5a (described later) of the via holes 5 are indicated by black dots.

The build-up conductor 2b mainly includes the strip-shaped conductor 2SS for signal and the solid conductor 2PS for power supply. Only land conductors for connection with the upper and lower conductors 2a and 2c are formed as the wiring conductor 2G for grounding.

The strip-shaped conductor 2SS for signal in the build-up conductor 2b is a narrow strip-shaped conductor with a width of about 5 to 30 μm. The strip-shaped conductor 2SS includes the strip-shaped conductor 2SSa extending from the area below the semiconductor-element mount portion 10A to the outer peripheral portion of the insulating substrate 1; and the strip-shaped conductor 2SSb extending only from the area below the semiconductor-element mount portion 10A to the area below the intermediate portion between the semiconductor-element mount portion 10A and the constant-voltage-regulator mount portion 10B. The strip-shaped conductor 2SS is electrically connected to the semiconductor-element connection pad 6S for signal via the via holes 5 in the upper layer in the area below the semiconductor-element mount portion 10A.

The solid conductor 2PS for power supply in the build-up conductor 2b extends from the area below the semiconductor-element mount portion 10A to the area below the constant-voltage-regulator mount portion 10B. The solid conductor 2PS for power supply is electrically connected in a thermally conductive manner to the semiconductor-element connection pad 6P for power supply via the via hole 5 in the upper layer in the area below the semiconductor-element mount portion 10A.

The solid conductor 2PS is electrically connected in a thermally conductive manner to the constant-voltage-regulator connection pads 7P for power supply via the via holes 5 disposed directly below the constant-voltage-regulator connection pads 7P for power supply and the sub-via holes 5a disposed directly below the spaces between the constant-voltage-regulator connection pads 7. The via holes 5 below the spaces between the constant-voltage-regulator connection pads 7 are defined as the sub-via holes 5a. The sub-via hole 5a connected to the solid conductor 2PS are disposed directly below the tongue pieces 7Pa added to the constant-voltage-regulator connection pads 7P for power supply.

The solid conductor 2PS for power supply is electrically connected in a thermally conductive manner to the external connection pad 8P for power supply via the through holes 4 and the via holes 5 in the area below the semiconductor-element mount portion 10A and the outer peripheral portion of the insulating substrate 1. Current for applying the power supply potential to the semiconductor element S via the solid conductor 2PS is supplied between the constant-voltage-regulator mount portion 10B and the semiconductor-element mount portion 10A.

In the build-up conductor 2b, the strip-shaped conductor 2SSb for signal extending from the area below the semiconductor-element mount portion 10A to the area below the intermediate portion between the semiconductor-element mount portion 10A and the constant-voltage-regulator mount portion 10B is formed; however, the strip-shaped conductor 2SS for signal extending from the area below the constant-voltage-regulator mount portion 10B is not formed. Hence, the arrangement of the via holes 5 and the sub-via holes 5a connected to the constant-voltage-regulator connection pads 7 in the upper layer is not restricted by the strip-shaped conductor 2SS for signal.

Accordingly, when the via holes 5 are disposed directly below the respective constant-voltage-regulator connection pads 7, and the sub-via holes 5a for grounding and for power supply are alternately arranged below the intermediate points between the respective constant-voltage-regulator connection pads 7, the number of via holes 5 and sub-via holes 5a connected to the solid conductor 2PS for power supply from the constant-voltage-regulator connection pads 7 in the upper layer is larger than that of a wiring board in related art, in the region corresponding to each constant-voltage-regulator mount portion 10B.

As described above, with the wiring board 13 in this embodiment, since the number of the via holes 5 and sub-via holes 5a that connect the constant-voltage-regulator connection pads 7P for power supply with the solid conductor 2PS for power supply in this layer is large, heat generated by the constant-voltage regulator V during operation can be highly efficiently transferred to the solid conductor 2PS for power supply in this layer.

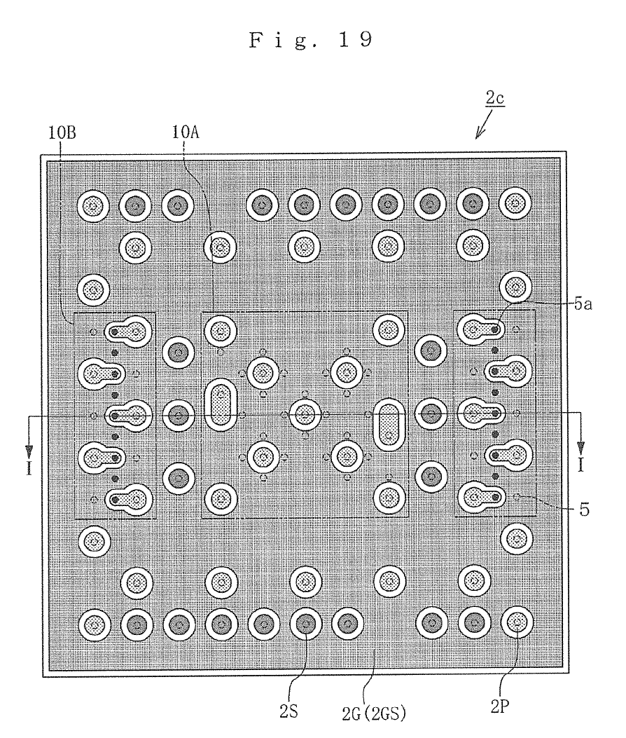

FIG. 19 illustrates the core conductor 2c applied on the upper surface of the core insulating layer 1c. In FIG. 19, the positions of the via holes 5 connected from the build-up conductor 2b in the upper layer are indicated by broken lines. The positions of the sub-via holes 5a (described later) of the via holes 5 are indicated by black dots.

The core conductor 2c mainly includes the solid conductor 2GS for grounding. Only land conductors for connection with the upper and lower conductors 2b and 2d are formed as the wiring conductor 2S for signal and the wiring conductor 2P for power supply.

The solid conductor 2GS for grounding in the core conductor 2c extends from the area below the semiconductor-element mount portion 10A to the area below the constant-voltage-regulator mount portion 10B. The solid conductor 2GS for grounding is electrically connected in a thermally conductive manner to the semiconductor-element connection pad 6G for grounding via the via holes 5 in the area below the semiconductor-element mount portion 10A. The solid conductor 2GS for grounding is also electrically connected in a thermally conductive manner to the constant-voltage-regulator connection pad 7G for grounding in the area below the constant-voltage-regulator mount portion 10B. The solid conductor 2GS for grounding is further electrically connected in a thermally conductive manner to the external connection pad 8G for grounding in the area below the semiconductor-element mount portion 10A and the outer peripheral portion of the insulating substrate 1. Current for applying the grounding potential to the semiconductor element S via the solid conductor 2GS is supplied between the constant-voltage-regulator mount portion 10B and the semiconductor-element mount portion 10A.

Heat generated by the constant-voltage regulator V during operation is transferred to the solid conductor 2GS for grounding in the core conductor 2c from the constant-voltage-regulator connection pad 7P for power supply via the via holes 5 and the sub-via holes 5a. This heat is transferred to the external connection pad 8P for power supply via the through holes 4 and the via holes 5 in the area below the semiconductor-element mount portion 10A and the outer peripheral portion of the insulating substrate 1, and is finally released to the outside via the external electric circuit board.

In the core conductor 2c, since the strip-shaped conductor 2SS for signal does not extend in the area below the constant-voltage-regulator mount portion 20B in the build-up conductor 2b in the upper layer, the arrangement of the via holes 5 and the sub-via holes 5a connected to the constant-voltage-regulator connection pads 7 is not restricted by the strip-shaped conductor 2SS for signal.

Accordingly, for example, when the via holes 5 are disposed directly below the respective constant-voltage-regulator connection pads 7, and the sub-via holes 5a for grounding and for power supply are alternately arranged below the intermediate points between the respective constant-voltage-regulator connection pads 7, the number of via holes 5 and sub-via holes 5a connected to the solid conductor 2GS for grounding in this layer from the constant-voltage-regulator connection pads 7 in the upper layer is larger than that of a wiring board 20 in related art in the region corresponding to each constant-voltage-regulator mount portion 10B.

As described above, since the number of the via holes 5 and sub-via holes 5a that connect the constant-voltage-regulator connection pads 7G for grounding with the solid conductor 2GS for grounding in this layer is large, heat generated by the constant-voltage regulator V during operation can be highly efficiently transferred to the solid conductor 2PS for grounding in this layer.

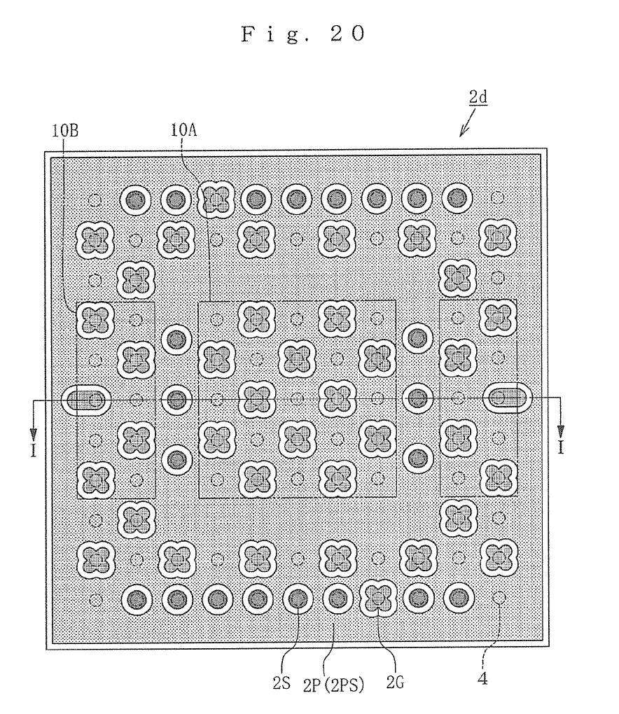

As illustrated in FIG. 20, the solid conductor 2PS for power supply in the core conductor 2d extends from the area below the semiconductor-element mount portion 10A to the area below the constant-voltage-regulator mount portion 10B. The solid conductor 2PS for power supply is electrically connected in a thermally conductive manner to the semiconductor-element connection pad 6P for power supply in the area below the semiconductor element mount portion 10A. The solid conductor 2PS for power supply is also electrically connected in a thermally conductive manner to the constant-voltage-regulator connection pad 7P for power supply in the area below the constant-voltage-regulator mount portion 10B. The solid conductor 2PS for power supply is further electrically connected in a thermally conductive manner to the external connection pad 8P for power supply in the area below the semiconductor-element mount portion 10A and the outer peripheral portion of the insulating substrate 1. Current for applying the power supply potential to the semiconductor element S via the solid conductor 2PS is supplied between the constant-voltage-regulator mount portion 10B and the semiconductor-element mount portion 10A.

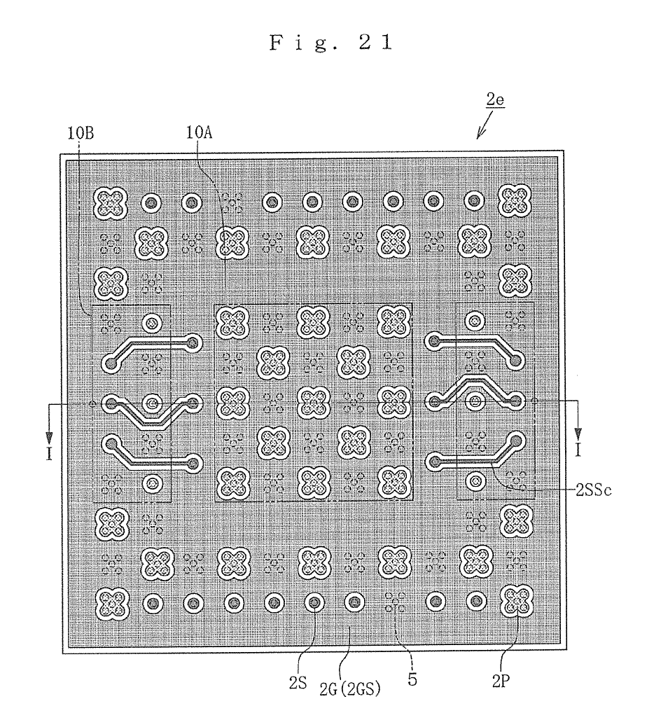

As illustrated in FIG. 21, the build-up conductor 2e mainly includes the strip-shaped conductor 2SSc for signal and the solid conductor 2GS for grounding. Only land conductors for connection with the upper and lower conductors 2d and 2f are formed as wiring conductor 2P for power supply.

The strip-shaped conductor 2SSc for signal in the build-up conductor 2e is a narrow strip-shaped conductor with a width of about 5 to 30 μm. The strip-shaped conductor 2SSc extends from the area below the intermediate portion between the semiconductor-element mount portion 10A and the constant-voltage-regulator mount portion 10B to the area below the constant-voltage-regulator mount portion 10B. The strip-shaped conductor 2SSc is electrically connected to the strip-shaped conductor 2SSb of the build-up conductor 2b via the through holes 4 for signal in the area below the intermediate portion between the semiconductor-element mount portion 10A and the constant-voltage-regulator mount portion 10B. The strip-shaped conductor 2SSc is also connected to the external connection pad 8S for signal in the area below the constant-voltage-regulator mount portion 10B.

The solid conductor 2GS for grounding in the build-up conductor 2e extends from the area below the semiconductor-element mount portion 10A to the area below the constant-voltage-regulator mount portion 10B. The solid conductor 2GS for grounding is electrically connected in a thermally conductive manner to the semiconductor-element connection pad 6G for grounding in the area below the semiconductor element mount portion 10A. The solid conductor 2GS for grounding is also electrically connected in a thermally conductive manner to the constant-voltage-regulator connection pad 7G for grounding in the area below the constant-voltage-regulator mount portion 10B. The solid conductor 2GS for grounding is further electrically connected in a thermally conductive manner to the external connection pad 8G for grounding in the area below the semiconductor-element mount portion 10A and the outer peripheral portion of the insulating substrate 1. Current for applying the grounding potential to the semiconductor element S via the solid conductor 2GS is supplied between the constant-voltage-regulator mount portion 10B and the semiconductor-element mount portion 10A.

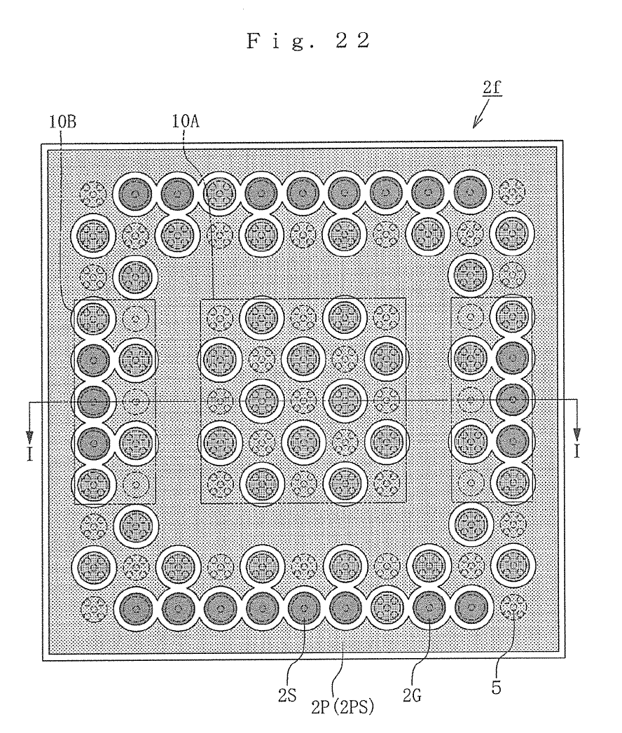

As illustrated in FIG. 22, the build-up conductor 2f mainly includes the solid conductor 2PS for power supply and the external connection pads 8S for signal, 8G for grounding, and 8P for power supply. The external connection pad 8S for signal is electrically connected to the strip-shaped conductor 2SS for signal via the through holes 4 and the via holes 5. The external connection pads 8G for grounding and 8P for power supply are electrically connected in a thermally conductive manner to the solid conductors 2GS for grounding and 2PS for power supply in the upper layer via the through holes 4 and the via holes 5.

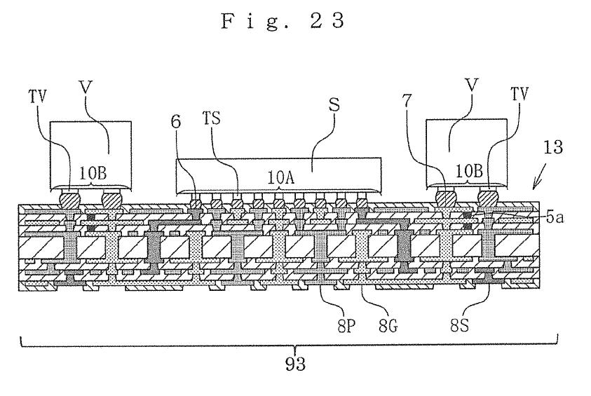

With the wiring board 13 in this embodiment, as illustrated in FIG. 23, the electrode terminal TS of the semiconductor element S is connected to the semiconductor-element connection pad 6 via solder, and the electrode terminal TV of the constant-voltage regulator V is connected to the constant-voltage-regulator connection pad 7 via solder. Accordingly, an electronic device 93 in which the semiconductor element S and the constant-voltage regulator V are mounted on the wiring board 13 is completed.

Heat generated by the constant-voltage regulator V during operation is properly transferred to the solid conductors 2GS for grounding and 2PS for power supply at the upper-surface side of the core insulating layer 1c from the constant-voltage-regulator connection pad 7 via the via holes 5 and the sub-via hole 5a. The heat is transferred from the solid conductors 2GS and 2PS to the external connection pad 8 in the area below the semiconductor-element mount portion 10A via the through holes 4 and the via hole 5. The heat is finally released to the outside via the external electric circuit board.

With the wiring board 13 in this embodiment and the electronic device 93 using the wiring board 13, regarding the wiring conductor 2S for signal extending from the area below the semiconductor-element mount portion 10A to the outer peripheral portion in the area below the constant-voltage-regulator mount portion 10B, the strip-shaped conductor 2SSc extending to the area below the constant-voltage-regulator mount portion 10B is on the surface of the build-up insulating layer 1d at the lower-surface side of the core insulating layer 1c; the constant-voltage-regulator connection pads 7G for grounding and 7P for power supply are electrically connected in a thermally conductive manner to the solid conductors 2GS for grounding and 2PS for power supply at the upper-surface side of the core insulating layer 1c via the plurality of via holes 5 and 5a in the build-up insulating layers 1a and 1b at the upper-surface side in the area below the constant-voltage-regulator connection pads 7 and the area below the spaces between the constant-voltage-regulator connection pads 7; and the solid conductors 2GS for grounding and 2PS for power supply at the upper-surface side of the core insulating layer 1c are electrically connected in a thermally conductive manner to the external connection pads 8G for grounding and 8P for power supply in the area below the semiconductor-element mount portion 10A via the through hole 4 in the core insulating layer 1c and the plurality of via holes 4 in the respective build-up insulating layers 1d to 1e at the lower-surface side in the area below the semiconductor-element mount portion 10A. Hence, heat generated by the constant-voltage regulator V during operation can be properly transferred to the solid conductor 2GS for grounding and the solid conductor 3PS for power supply at the upper-surface side of the core insulating layer 1c, and can be released to the outside. Accordingly, the wiring board 13 that allows the semiconductor element S to stably operate and the electronic device 93 using the wiring board 13 can be provided.

### Fourth Embodiment

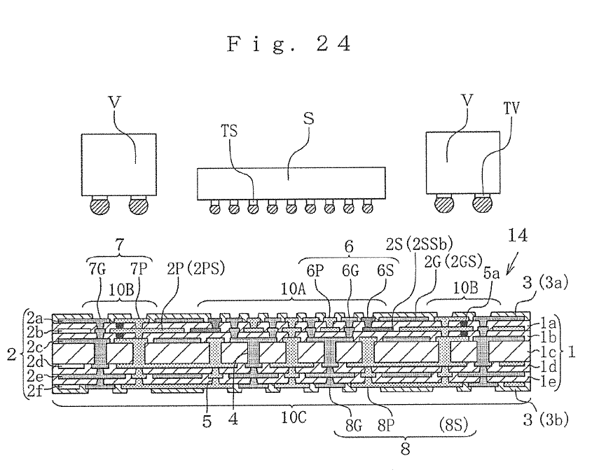

A wiring board according to a fourth embodiment of the present disclosure is described with reference to FIGS. 24 to 30. The same reference numerals as those of the first embodiment are applied to the same members as those of the first embodiment, and the redundant description is omitted. The description on the drawings for the same configurations as those of the above-described embodiment is also omitted. The schematic top view of the build-up conductor 2a in the uppermost layer in the wiring board 14 according to the present disclosure is the same as that in FIG. 17 according to the third embodiment, and hence is omitted.

FIG. 24 is a schematic cross-sectional view illustrating a wiring board 14 of this example. In the wiring board 14, only the external connection pads 8G for grounding and 8P for power supply of the external connection pad 8 are disposed at the external connection surface 10C below the constant-voltage-regulator mount portion 10B. The external connection pads 8G for grounding and 8P for power supply below the constant-voltage-regulator mount portion 10B are electrically connected in a thermally conductive manner to the constant-voltage-regulator connection pads 7G for grounding and 7P for power supply via the sub-via holes 5a and the through holes 4 disposed from the upper surface to the lower surface of the insulating substrate 1 in the area below the constant-voltage-regulator mount portion 10B. Since the external connection pad 8S for signal is not disposed below the constant-voltage-regulator mount portion 10B, the external connection pad 8S for signal is not illustrated.

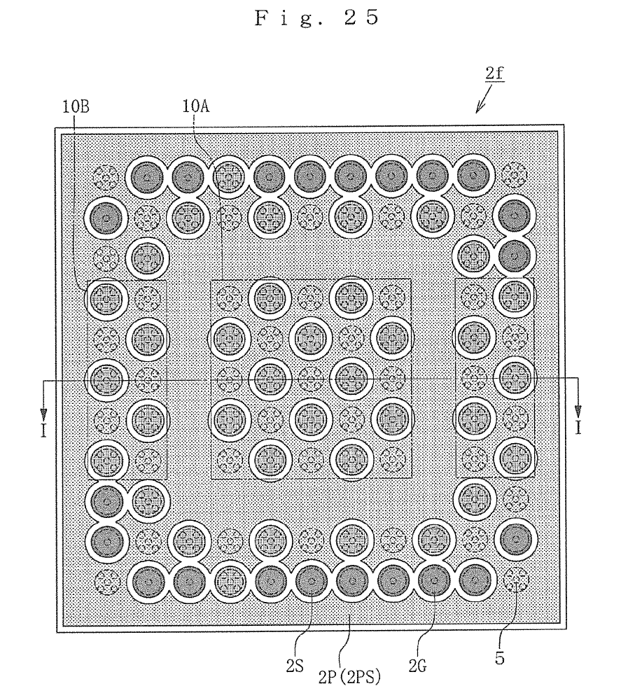

FIG. 25 illustrates the upper surface of the build-up conductor 2f in the lowermost layer. The positions of the via holes 5 connected to the build-up conductor 2e in the upper layer and the position of the opening in the solder resist layer 3b at the lower-surface side are indicated by broken lines.

The build-up conductor 2f mainly includes the solid conductor 2PS for power supply and the external connection pads 8S for signal, 8G for grounding, and 8P for power supply. A plurality of the external connection pad 8S for signal is disposed mainly in the outer peripheral portion of the insulating substrate 1. The external connection pad 8S for signal is not disposed below the constant-voltage-regulator mount portion 10B.

A plurality of the external connection pads 8G for grounding and 8P for power supply is mainly disposed below the semiconductor-element mount portion 10A and below the constant-voltage-regulator mount portion 10B. Only the external connection pad 8G for grounding and the external connection pad 8P for power supply are disposed below the constant-voltage-regulator mount portion 10B. The external connection pads 8G for grounding and 8P for power supply are electrically connected in a thermally conductive manner to the solid conductors 2GS for grounding and 2PS for power supply in the upper layer via the through holes 4 and the via holes 5.

The solid conductor 2PS for power supply in this layer is integrally formed with the external connection pad 8P for power supply, and extends in a large region including the area below the semiconductor-element mount portion 10A and the area below the constant-voltage-regulator mount portion 10B. Current for applying the power supply potential to the semiconductor element S via the solid conductor 2PS is supplied between the constant-voltage-regulator mount portion 10B and the semiconductor-element mount portion 10A.

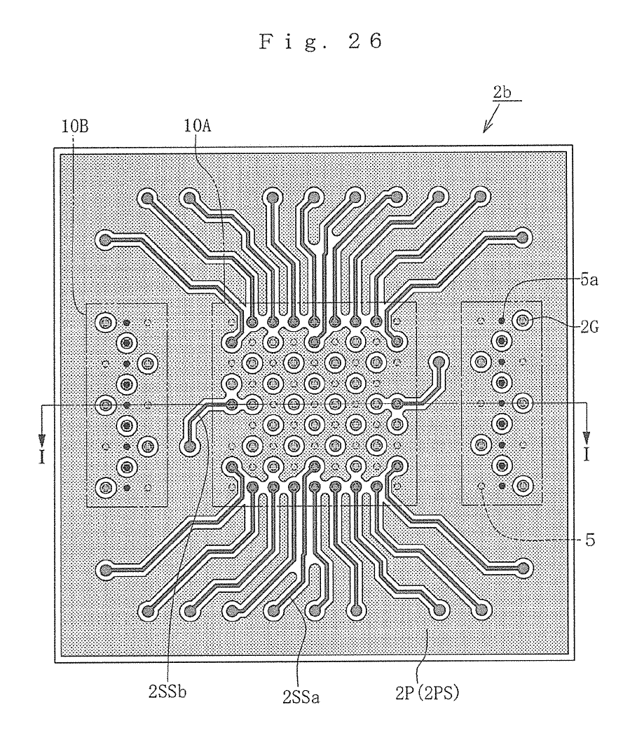

FIG. 26 illustrates the upper surface of the second build-up conductor 2b from the top. The positions of the via holes 5 connected from the build-up conductor 2a in the upper layer are indicated by broken lines. The positions of the sub-via holes 5a (described later) of the via holes 5 are indicated by black dots.

The build-up conductor 2b mainly includes the strip-shaped conductors 2SSa and 2SSb for signal and the solid conductor 2PS for power supply. Only land conductors for connection with the upper and lower conductors 2a and 2c are formed as the wiring conductor 2G for grounding.

The strip-shaped conductors 2SSa and 2SSb for signal in the build-up conductor 2b are narrow strip-shaped conductors each having a width of about 5 to 30 μm. The strip-shaped conductor 2SSa extends from the area below the semiconductor-element mount portion 10A to the outer peripheral portion of the insulating substrate 1. The strip-shaped conductor 2SSb extends from the area below the semiconductor-element mount portion 10A to the area below the intermediate portion between the semiconductor-element mount portion 10A and the constant-voltage-regulator mount portion 10B. The strip-shaped conductors 2SSa and 2SSb are electrically connected to the semiconductor-element connection pad 6S for signal via the via holes 5 in the upper layer in the area below the semiconductor-element mount portion 10A. The strip-shaped conductors 2SSa and 2SSb do not extend to the area below the constant-voltage-regulator mount portion 10B.

The solid conductor 2PS for power supply in the build-up conductor 2b extends in a large region including the area below the semiconductor-element mount portion 10A and the area below the constant-voltage-regulator mount portion 10B. The solid conductor 2PS for power supply is electrically connected in a thermally conductive manner to the semiconductor-element connection pad 6P for power supply via the via holes 5 in the upper layer in the area below the semiconductor-element mount portion 10A.

The solid conductor 2PS is electrically connected in a thermally conductive manner to the constant-voltage-regulator connection pads 7P for power supply via the via holes 5 disposed directly below the constant-voltage-regulator connection pads 7P for power supply and the sub-via holes 5a disposed directly below the spaces between the constant-voltage-regulator connection pads 7. The via holes 5 below the spaces between the constant-voltage-regulator connection pads 7 are defined as the sub-via holes 5a. The sub-via holes 5a connected to the solid conductor 2PS are disposed directly below the tongue pieces 7Pa added to the constant-voltage-regulator connection pads 7P for power supply.

The solid conductor 2PS for power supply is further electrically connected in a thermally conductive manner to the external connection pad 8P for power supply via the through holes 4 and the via holes 5 in the area below the semiconductor-element mount portion 10A and the area below the constant-voltage-regulator mount portion 10B. Current for applying the power supply potential to the semiconductor element S via the solid conductor 2PS is supplied between the constant-voltage-regulator mount portion 10B and the semiconductor-element mount portion 10A.

The build-up conductor 2b has the strip-shaped conductor 2SSb extending from the area below the semiconductor-element mount portion 10A to the area below the intermediate portion between the semiconductor-element mount portion 10A and the constant-voltage-regulator mount portion 10B. However, the build-up conductor 2b does not have the strip-shaped conductors 2SSa and 2SSb for signal extending in the area below the constant-voltage-regulator mount portion 10B. Hence, the arrangement of the via holes 5 and the sub-via hole 5a connected to the constant-voltage-regulator connection pads 7 in the upper layer is not restricted by the strip-shaped conductor 2SS for signal.

Accordingly, when the via holes 5 are disposed directly below the respective constant-voltage-regulator connection pads 7, and the sub-via holes 5a for grounding and for power supply are alternately arranged below the intermediate points between the respective constant-voltage-regulator connection pads 7, the number of via holes 5 and sub-via holes 5a connected to the solid conductor 2PS for power supply from the constant-voltage-regulator connection pads 7 in the upper layer is larger than that of the wiring board 20 in related art, in the area below each constant-voltage-regulator mount portion 10B.

As described above, with the wiring board 14 in this embodiment, since the number of the via holes 5 and sub-via holes 5a that connect the constant-voltage-regulator connection pads 7P for power supply with the solid conductor 2PS for power supply in this layer is large, heat generated by the constant-voltage regulator V during operation can be highly efficiently transferred to the solid conductor 2PS for power supply in this layer.

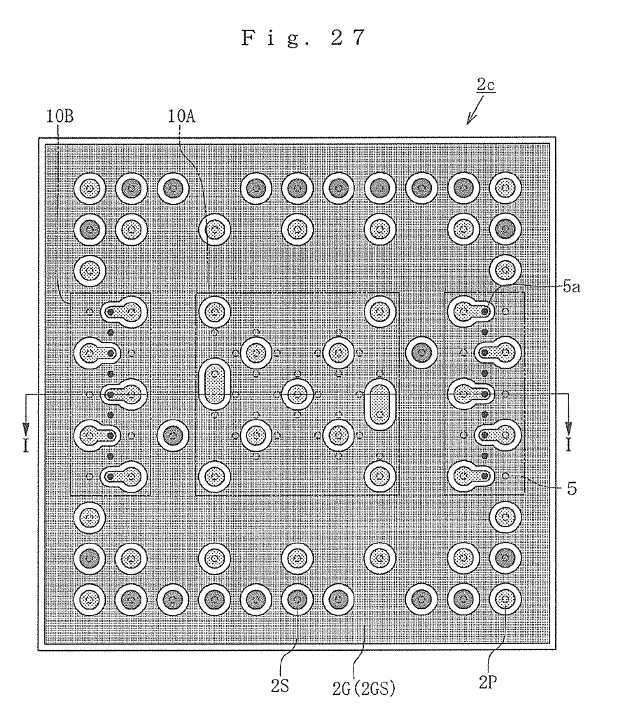

FIG. 27 illustrates the core conductor 2c applied on the upper surface of the core insulating layer 1c. The positions of the via holes 5 connected from the build-up conductor 2b in the upper layer are indicated by broken lines. The positions of the sub-via hole 5a of the via holes 5 are indicated by black dots.

The core conductor 2c mainly includes the solid conductor 2GS for grounding. Only land conductors for connection with the upper and lower conductors 2b and 2d are formed as the wiring conductor 2S for signal and the wiring conductor 2P for power supply.

The solid conductor 2GS for grounding in the core conductor 2c extends in a large region including the area below the semiconductor-element mount portion 10A and the area below the constant-voltage-regulator mount portion 10B. The solid conductor 2GS for grounding is electrically connected in a thermally conductive manner to the semiconductor-element connection pad 6G for grounding via the via holes 5 in the area below the semiconductor-element mount portion 10A. The solid conductor 2GS for grounding is also electrically connected in a thermally conductive manner to the constant-voltage-regulator connection pad 7G for grounding in the area below the constant-voltage-regulator mount portion 10B. The solid conductor 2GS for grounding is further electrically connected in a thermally conductive manner to the external connection pad 8G for grounding in the area below the semiconductor-element mount portion 10A and the area below the constant-voltage-regulator mount portion 10B. Current for applying the grounding potential to the semiconductor element S via the solid conductor 2GS is supplied between the constant-voltage-regulator mount portion 10B and the semiconductor-element mount portion 10A.

Heat generated by the constant-voltage regulator V during operation is transferred to the solid conductor 2GS for grounding in the core conductor 2c from the constant-voltage-regulator connection pad 7G for grounding via the via holes 5 and the sub-via holes 5a. This heat is transferred to the external connection pad 8G for grounding via the through holes 4 and the via holes 5 in the area below the semiconductor-element mount portion 10A and the outer peripheral portion of the insulating substrate 1, and is finally released to the outside via the external electric circuit board.

In the core conductor 2c, since the strip-shaped conductors 2SSa and 2SSb for signal do not extend in the area below the constant-voltage-regulator mount portion 10B in the build-up conductor 2b in the upper layer, the arrangement of the via holes 5 and the sub-via holes 5a connected to the constant-voltage-regulator connection pads 7 is not restricted by the strip-shaped conductors 2SSa and 2SSb for signal.

Accordingly, when the via holes 5 are disposed directly below the respective constant-voltage-regulator connection pads 7, and the sub-via holes 5a for grounding and for power supply are alternately arranged below the intermediate points between the respective constant-voltage-regulator connection pads 7, the number of via holes 5 and sub-via holes 5a connected to the solid conductor 2GS for grounding in this layer from the constant-voltage-regulator connection pad 7 in the upper layer is larger than that of the wiring board in related art, in the area below each constant-voltage-regulator mount portion 10B.

As described above, since the number of the via holes 5 and sub-via holes 5a that connect the constant-voltage-regulator connection pads 7G for grounding with the solid conductor 2GS for grounding in this layer is large, heat generated by the constant-voltage regulator V during operation can be highly efficiently transferred to the solid conductor 2GS for grounding in this layer.

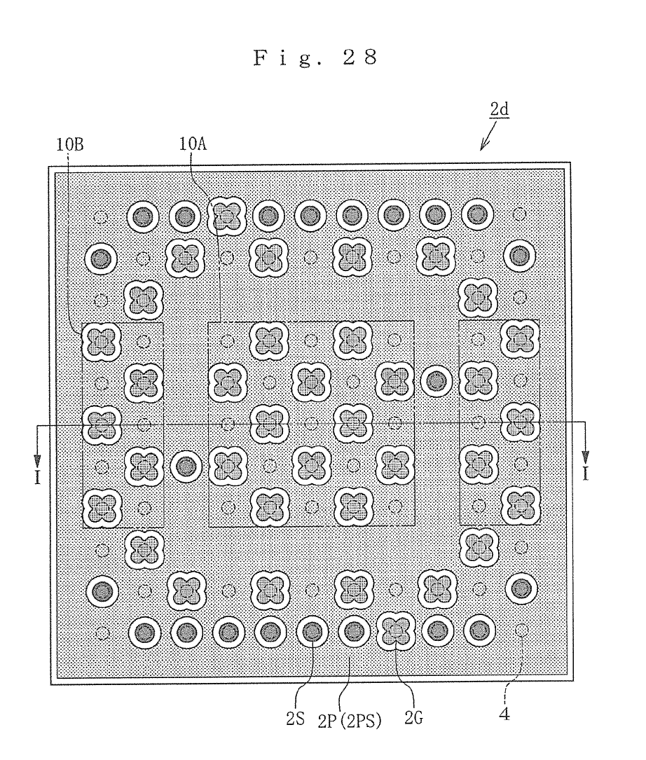

FIG. 28 illustrates the upper surface of the core conductor 2d applied on the lower surface of the core insulating layer 1c. In FIG. 28, the positions of the through holes 4 connected from the core conductor 2c in the upper layer are indicated by broken lines.

The core conductor 2d mainly includes the solid conductor 2PS for power supply. Only land conductors for connection with the upper and lower conductors 2c and 2e are formed as the wiring conductor 2S for signal and the wiring conductor 2G for grounding. The land conductor for grounding has a flower-like different shape for connecting the plurality of via holes 5 to the build-up conductor 2e in the lower layer.

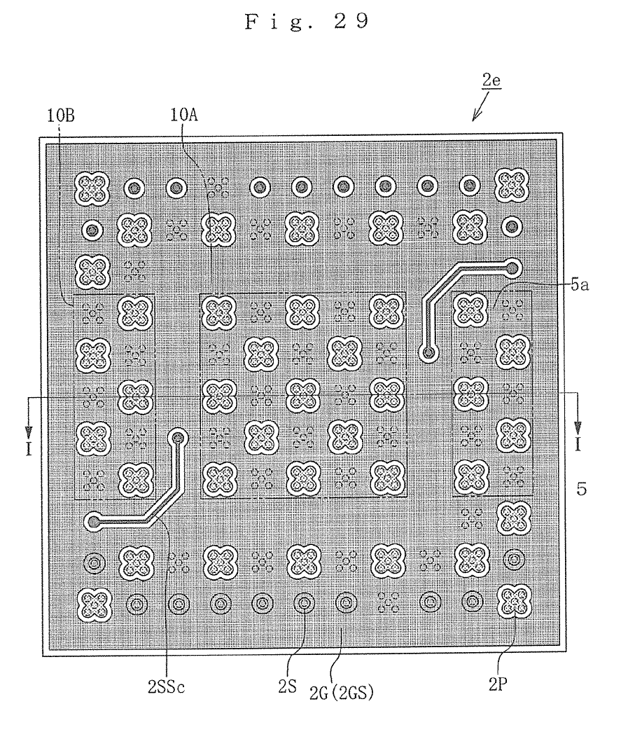

FIG. 29 illustrates the upper surface of the second build-up conductor 2e from the top. The build-up conductor 2e mainly includes the solid conductor 2GS for grounding. The wiring conductor 2S for signal has the strip-shaped conductor 2SSc and the land conductor. Only a land conductor is formed as the wiring conductor 2P for power supply. The land conductor for power supply has a flower-like different shape for connecting a plurality of the via holes 5 to the upper and lower conductors 2d and 2f.

The strip-shaped conductor 2SSc for signal in the build-up conductor 2e is a narrow strip-shaped conductor with a width of about 5 to 30 μm. The strip-shaped conductor 2SSc extends from the area below the intermediate portion between the semiconductor-element mount portion 10A and the constant-voltage-regulator mount portion 10B to the outer peripheral portion of the wiring board 1. The strip-shaped conductor 2SSc does not extend to the area below the constant-voltage-regulator mount portion 10B. The strip-shaped conductor 2SSc is electrically connected to the strip-shaped conductor 2SSb of the build-up conductor 2b via the through holes 4 for signal in the area below the intermediate portion between the semiconductor-element mount portion 10A and the constant-voltage-regulator mount portion 10B. The strip-shaped conductor 2SSc is also connected to the external connection pad 8S for signal in the outer peripheral portion of the insulating substrate 1. The solid conductor 2GS for grounding in the build-up conductor 2e extends in a large region including an area from the area below the semiconductor-element mount portion 10A to the area below the constant-voltage-regulator mount portion 10B. Other structures are similar to those described for the wiring board 13 according to the third embodiment.

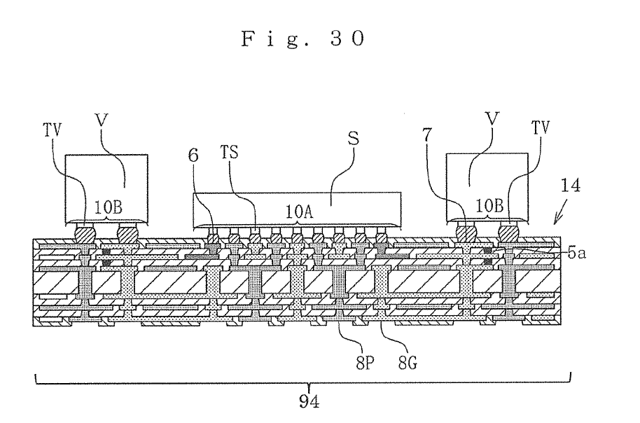

With the wiring board 14 in this embodiment, as illustrated in FIG. 30, the electrode terminal TS of the semiconductor element S is connected to the semiconductor-element connection pad 6 via solder, and the electrode terminal TV of the constant-voltage regulator V is connected to the constant-voltage-regulator connection pad 7 via solder. Accordingly, an electronic device 94 in which the semiconductor element S and the constant-voltage regulator V are mounted on the wiring board 14 is completed.

In the electronic device 94, heat generated by the constant-voltage regulator V during operation is properly transferred to the solid conductors 2GS for grounding and 2PS for power supply at the upper-surface side of the core insulating layer 1c from the constant-voltage-regulator connection pad 7 via the via holes 5 and the sub-via hole 5a. The heat is transferred from the solid conductors 2GS and 2PS to the external connection pad 8 below the constant-voltage-regulator mount portion 10B via the through holes 4 and the via hole 5. The heat is finally released to the outside via the external electric circuit board.

As described above, with the wiring board 14 and the electronic device 94 using the wiring board 14 according to this embodiment, only the external connection pads 8G for grounding and 8P for power supply of the external connection pads 8 are disposed at the external connection surface 10C below the constant-voltage-regulator mount portion 10B; and the external connection pads 8G for grounding and 8P for power supply in the area below the constant-voltage-regulator mount portion 10B are electrically connected in a thermally conductive manner to the constant-voltage-regulator connection pads 7G for grounding and 7P for power supply via the plurality of via holes 5 and the plurality of through holes 4 disposed from the upper surface to the lower surface of the insulating substrate 1 in the area below the constant-voltage-regulator mount portion 10B. Hence, heat generated by the constant-voltage regulator V during operation can be properly transferred to the external connection pads 8G and 8P disposed below the constant-voltage-regulator mount portion 10B. The heat can be properly released to the outside. Accordingly, the wiring board 14 that allows the semiconductor element S to stably operate and the electronic device 94 using the wiring board 14 can be provided.

### Fifth Embodiment

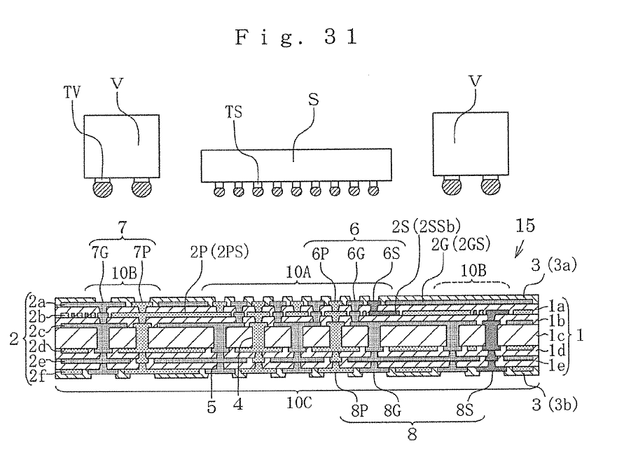

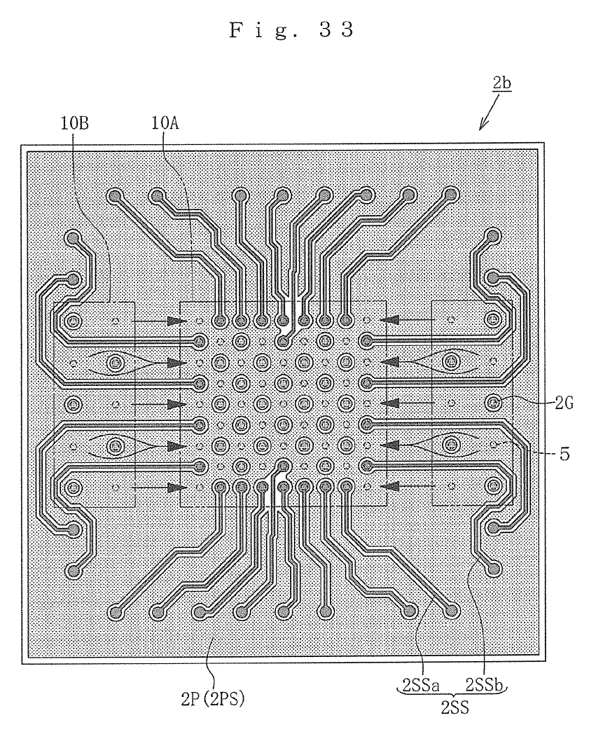

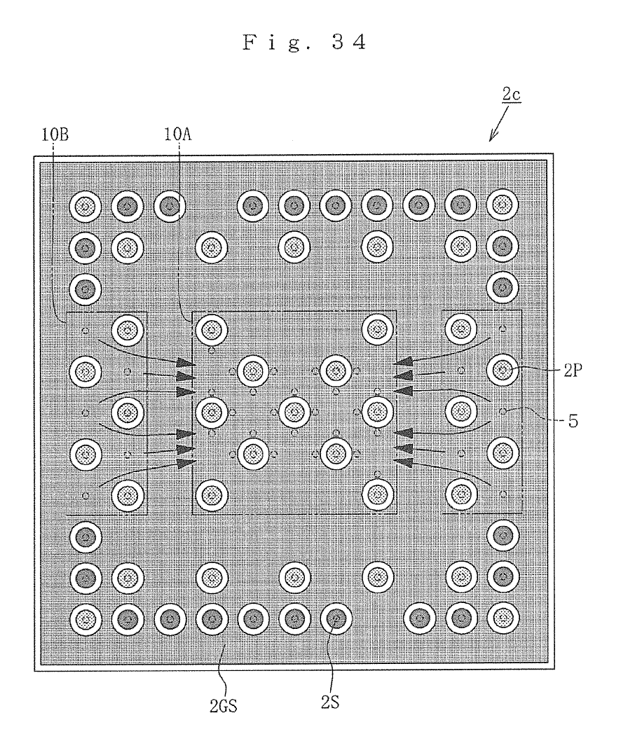

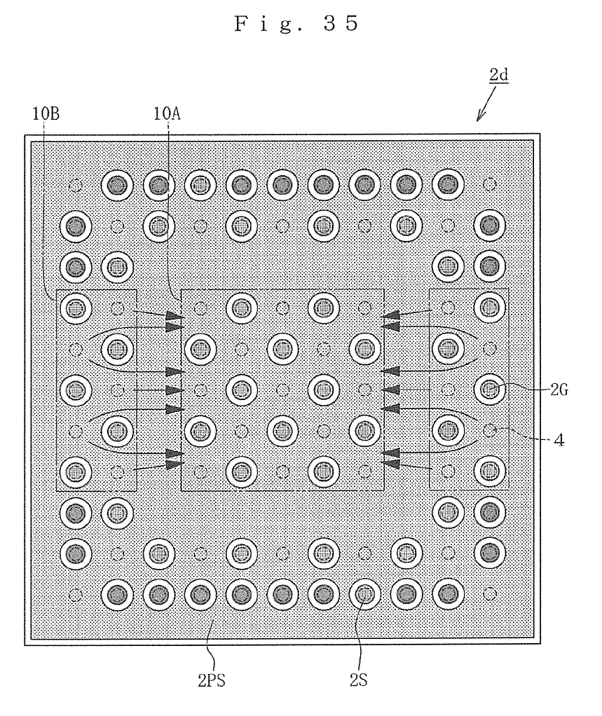

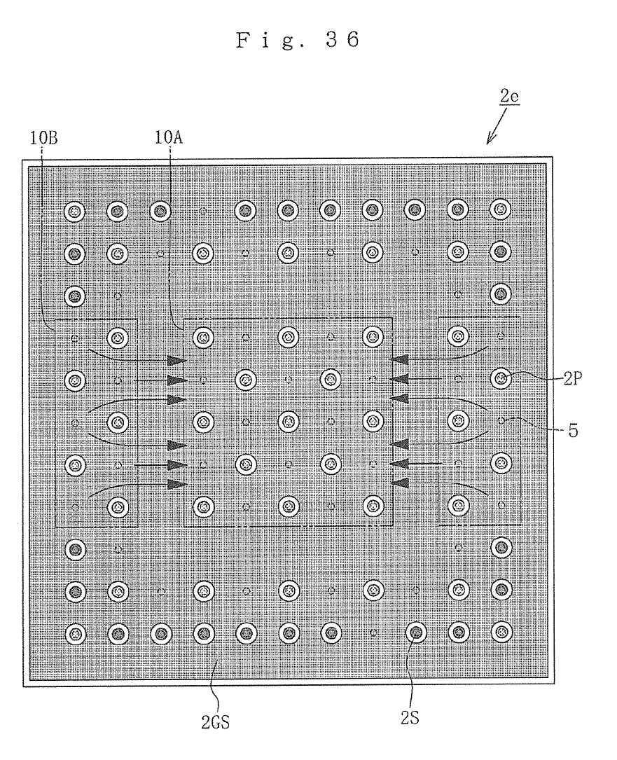

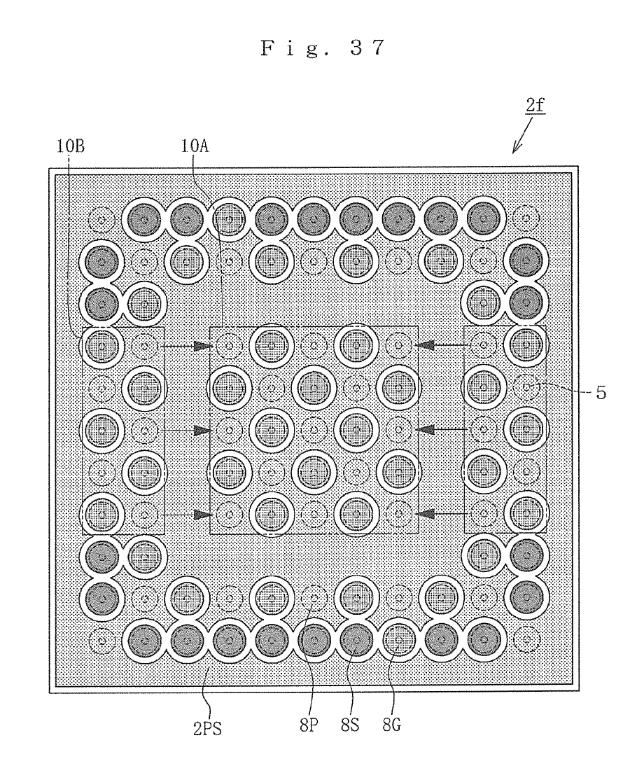

A wiring board according to a fifth embodiment of the present disclosure is described with reference to FIGS. 31 to 38. The same reference numerals as those of the first embodiment are applied to the same members as those of the first embodiment, and the redundant description is omitted. The description on the drawings for the same configurations as those of the above-described embodiment is also omitted.

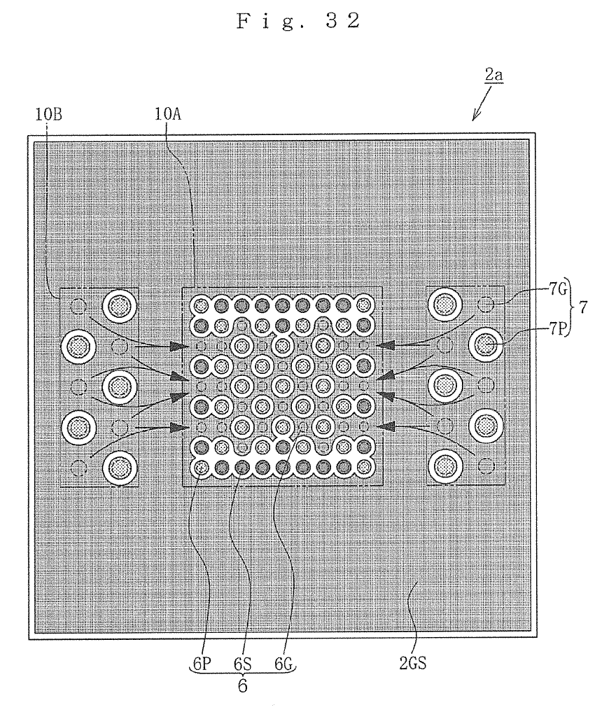

As illustrated in FIGS. 31 and 32, the build-up conductor 2a includes a plurality of the semiconductor-element connection pads 6 in the region corresponding to the mount portion 10A. The semiconductor-element connection pads 6 include a semiconductor-element connection pad 6S for signal, a semiconductor-element connection pad 6G for grounding, and a semiconductor-element connection pad 6P for power supply. A plurality of the semiconductor-element connection pads 6S for signal is mainly disposed at positions corresponding to an outer peripheral portion of the semiconductor-element mount portion 10A. Multiple semiconductor-element connection pads 6G for grounding and 6P for power supply are mainly at positions corresponding to a center portion of the semiconductor element mount portion 10A.

The strip-shaped conductors 2SS for signal in the build-up conductor 2b include the strip-shaped conductor 2SSa extending from the area below the semiconductor-element mount portion 10A to the outer peripheral portion of the insulating substrate 1 without passing through the area below the intermediate portion between the semiconductor-element mount portion 10A and the constant-voltage-regulator mount portion 10B; and the strip-shaped conductor 2SSb extending from the area below the semiconductor-element mount portion 10A, passing through the area below the intermediate portion between the semiconductor-element mount portion 10A and the constant-voltage-regulator mount portion 10B, and extending to the outer peripheral portion of the insulating substrate 1. The strip-shaped conductors 2SS for signal are electrically connected to the semiconductor-element connection pad 6S for signal via the via hole 5 in the upper layer, in the area below the semiconductor-element mount portion 10A. Accordingly, the strip-shaped conductors 2SS are electrically connected to the external connection pad 8S in the outer peripheral portion of the insulating substrate 1 via the through hole 4 and the via hole 5 in the lower layer. The strip-shaped conductors 2SS for signal are each a narrow strip-shaped conductor with a width of about 5 to 30 μm.

The strip-shaped conductor 2SSb for signal in the build-up conductor 2b extends in the arrangement direction of the semiconductor-element mount portion 10A and the constant-voltage-regulator mount portion 10B, and further extends to the area above the external connection pad 8 through the outer-periphery side of the via holes 5 connected to the constant-voltage-regulator connection pad 7 in the insulating substrate 1. Hence, nothing significantly blocks current supply from the area below the semiconductor-element mount portion 10A to the area below the constant-voltage-regulator mount portion 10B. Accordingly, the current for applying the power supply potential to the semiconductor element S via the solid conductor 2PS for power supply in the build-up conductor 2b can be properly supplied from the constant-voltage regulator V.

The build-up conductor 2a, the core conductor 2c, and build-up conductors 2d, 2e, and 2f illustrated in FIGS. 32 and 34 to 37 are similar to those according to the first embodiment, and hence the redundant description is omitted.

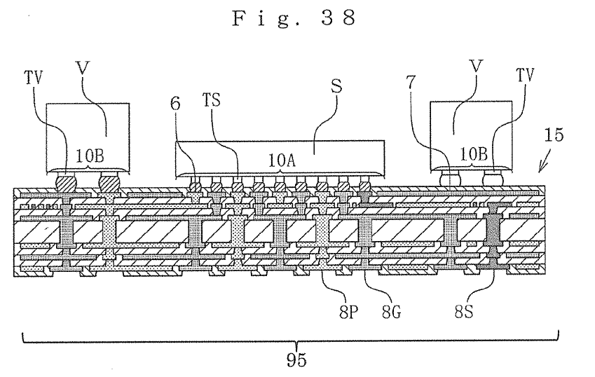

With the wiring board 15 in this embodiment, as illustrated in FIG. 38, the electrode terminal TS of the semiconductor element S is connected to the semiconductor-element connection pad 6 via solder, and the electrode terminal TV of the constant-voltage regulator V is connected to the constant-voltage-regulator connection pad 7 via solder. Accordingly, an electronic device 95 in which the semiconductor element S and the constant-voltage regulator V are mounted on the wiring board 15 is completed.

As described above, with the wiring board 15 in this embodiment and the electronic device 95, the strip-shaped conductors 2SS for signal include the strip-shaped conductor 2SSb for signal extending on the surface of the build-up insulating layer 1b, on which the solid conductor 2PS for power supply extends, in the arrangement direction of the semiconductor-element mount portion 10A and the constant-voltage-regulator mount portion 10B, along a wiring path extending from the area below the semiconductor-element mount portion 10A to the area below the constant-voltage-regulator mount portion 10B. The strip-shaped conductor 2SSb for signal further extends to the area above the external connection pad 8 through the outer-periphery side with respect to the via holes 5 connected to the constant-voltage-regulator connection pad 7 in the insulating substrate 1. Accordingly, the current path of the solid conductor 2PS for power supply on the surface of the build-up insulating layer 1b having the strip-shaped conductor 2SSb for signal from the area directly below the constant-voltage-regulator mount portion 10B to the area directly below the semiconductor-element mount portion 10A is not significantly blocked by the strip-shaped conductor 2SSb for signal. Hence, current can be sufficiently supplied to the semiconductor element S via the solid conductor 2PS. Accordingly, the wiring board 15 that allows the semiconductor element S to stably operate and the electronic device 95 using the wiring board 15 can be provided.

Other examples are described below for the second build-up conductor 2b from the top relating to the wiring board 15 according to the present disclosure.

These examples each have a layer structure similar to that of the above-described wiring board 15, the same reference numeral is applied to the same member, and the detailed description thereof is omitted.

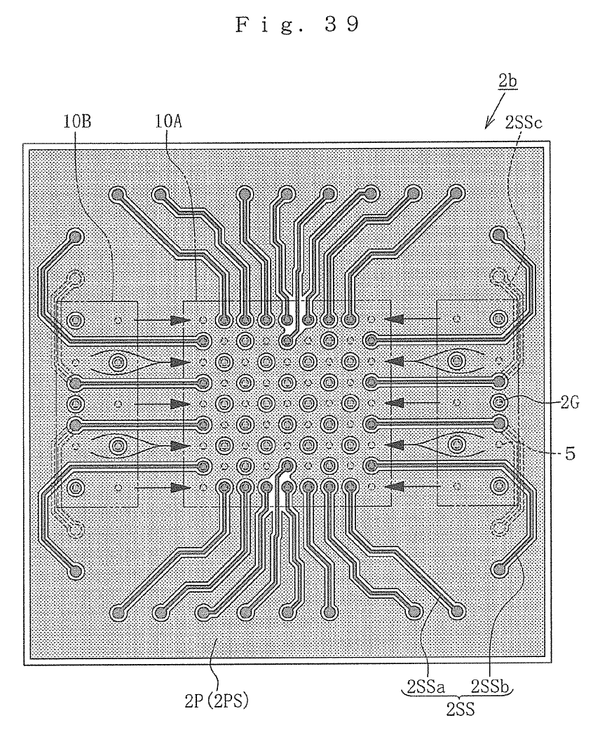

In FIGS. 39 to 42 described below, the build-up conductor 2b on the surface of the second build-up insulating layer 1b from the top of the wiring board 15 according to the present disclosure is indicated by solid lines. The positions of the via holes 5 connected from the build-up conductor 2a in the upper layer and the wiring conductor 2S in the build-up conductor 2e on the surface of the second build-up insulating layer 1d from the bottom are indicated by broken lines.

In the examples in FIGS. 39 to 42, the build-up conductor 2b mainly includes the strip-shaped conductor 2SS for signal and the solid conductor 2PS for power supply. For the wiring conductor 2G for grounding, only a circular land conductor for connection with the upper and lower conductors 2a and 2c is formed. The build-up conductor 2e has the strip-shaped conductor 2SSc for signal.

The strip-shaped conductors 2SS for signal in the build-up conductor 2b illustrated in FIG. 39 include the strip-shaped conductor 2SSa for signal extending from the area below the semiconductor-element mount portion 10A to the outer peripheral portion of the insulating substrate 1 without passing through the area below the intermediate portion between the semiconductor-element mount portion 10A and the constant-voltage-regulator mount portion 10B; and the strip-shaped conductor 2SSb for signal extending from the area below the semiconductor-element mount portion 10A, passing through the area below the intermediate portion between the semiconductor-element mount portion 10A and the constant-voltage-regulator mount portion 10B, and extending to the outer peripheral portion of the insulating substrate 1.

The strip-shaped conductors 2SS for signal are electrically connected to the semiconductor-element connection pads 6S for signal via the via holes 5 in the upper layer in the area below the semiconductor-element mount portion 10A. The strip-shaped conductors 2SS for signal are also electrically connected to the external connection pads 8S in the outer peripheral portion of the insulating substrate 1 via the through holes 4 and the via holes 5 in the lower layer or via the strip-shaped conductor 2SSc of the build-up conductor 2e in addition to the through holes 4 and the via holes 5.

A portion of the strip-shaped conductor 2SSb extends in the arrangement direction of the semiconductor-element mount portion 10A and the constant-voltage-regulator mount portion 10B. The portion of the strip-shaped conductor 2SSb for signal further extends to the area above the external connection pad 8 through the outer-periphery side with respect to the via holes 5 connected to the constant-voltage-regulator connection pad 7 in the insulating substrate 1.

Another portion of the strip-shaped conductor 2SSb extends in the arrangement direction of the semiconductor-element mount portion 10A and the constant-voltage-regulator mount portion 10B and extends to a middle position in the area below the constant-voltage-regulator mount portion 10B. The other portion of the strip-shaped conductor 2SSb is connected to the strip-shaped conductor 2SSc disposed in the build-up conductor 2e. The strip-shaped conductor 2SSc extends to the area above the external connection pad 8 through the outer-periphery side with respect to the via holes 5 connected to the constant-voltage-regulator connection pad 7 in the insulating substrate 1.

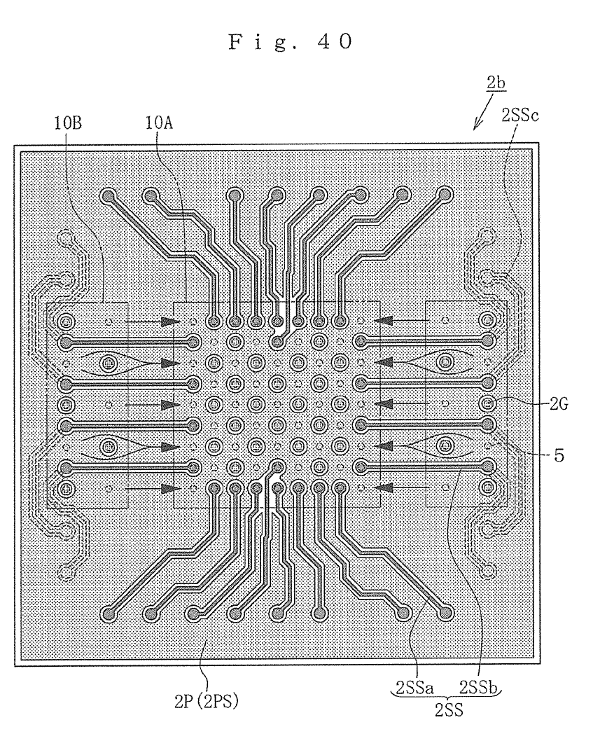

The strip-shaped conductors 2SS for signal of the build-up conductor 2b illustrated in FIG. 40 include the strip-shaped conductor 2SSa and the strip-shaped conductor 2SSb similarly to the example illustrated in FIG. 39 (described above).

The strip-shaped conductors 2SS for signal are electrically connected to the semiconductor-element connection pads 6S for signal via the via holes 5 in the upper layer in the area below the semiconductor-element mount portion 10A. The strip-shaped conductors 2SS for signal are also electrically connected to the external connection pads 8S in the outer peripheral portion of the insulating substrate 1 via the through holes 4 and the via holes 5 in the lower layer or via the strip-shaped conductor 2SSc of the build-up conductor 2e in addition to the through holes 4 and the via holes 5.

The strip-shaped conductor 2SSb extending in the area blow the constant-voltage-regulator mount portion 10B extends in the arrangement direction of the semiconductor-element mount portion 10A and the constant-voltage-regulator mount portion 10B to a middle position in the area below the constant-voltage-regulator mount portion 10B. The strip-shaped conductor 2SSb is connected to the strip-shaped conductor 2SSc in the build-up conductor 2e. The strip-shaped conductor 2SSc extends to the area above the external connection pad 8 through the outer-periphery side with respect to the via holes 5 connected to the constant-voltage-regulator connection pad 7 in the insulating substrate 1.

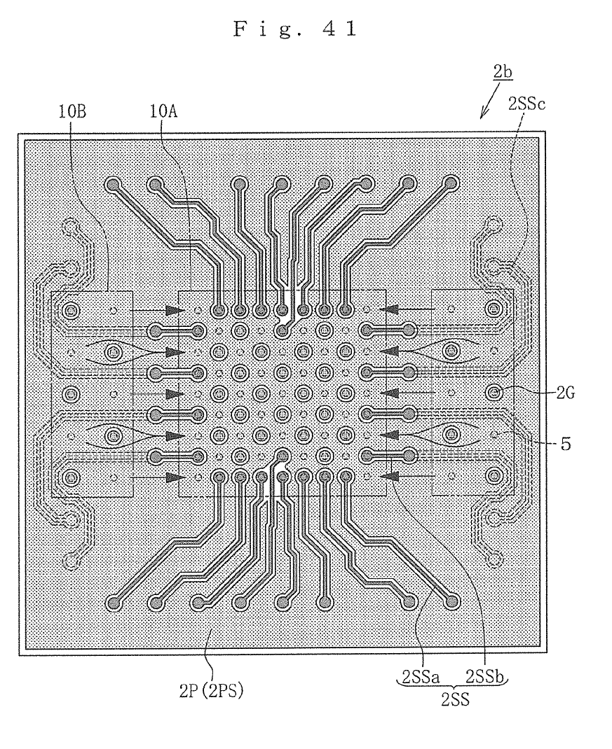

The strip-shaped conductors 2SS for signal in the build-up conductor 2b illustrated in FIG. 41 include the strip-shaped conductor 2SSa extending from the area below the semiconductor-element mount portion 10A to the outer peripheral portion of the insulating substrate 1 without passing through the area below the intermediate portion between the semiconductor-element mount portion 10A and the constant-voltage-regulator mount portion 10B; and the strip-shaped conductor 2SSb extending from the area below the semiconductor-element mount portion 10A to the area below the intermediate portion between the semiconductor-element mount portion 10A and the constant-voltage-regulator mount portion 10B.

The strip-shaped conductors 2SS are electrically connected to the semiconductor-element connection pads 6S for signal via the via holes 5 in the upper layer in the area below the semiconductor-element mount portion 10A. Also, the strip-shaped conductors 2SS are electrically connected to the external connection pad 8 in the outer peripheral portion of the insulating substrate 1 via the through holes 4 and the via holes in the lower layer. Alternatively, the strip-shaped conductors 2SS are electrically connected to the strip-shaped conductor 2SSc of the build-up conductor 2e in the area below the intermediate portion between the semiconductor-element mount portion 10A and the constant-voltage-regulator mount portion 10B.

The strip-shaped conductor 2SSb extends in the arrangement direction of the semiconductor-element mount portion 10A and the constant-voltage-regulator mount portion 10B. The strip-shaped conductor 2SSb is connected to the strip-shaped conductor 2SSc in the build-up conductor 2e. The strip-shaped conductor 2SSc extends to the area above the external connection pad 8 through the outer-periphery side with respect to the via holes 5 connected to the constant-voltage-regulator connection pad 7 in the insulating substrate 1.

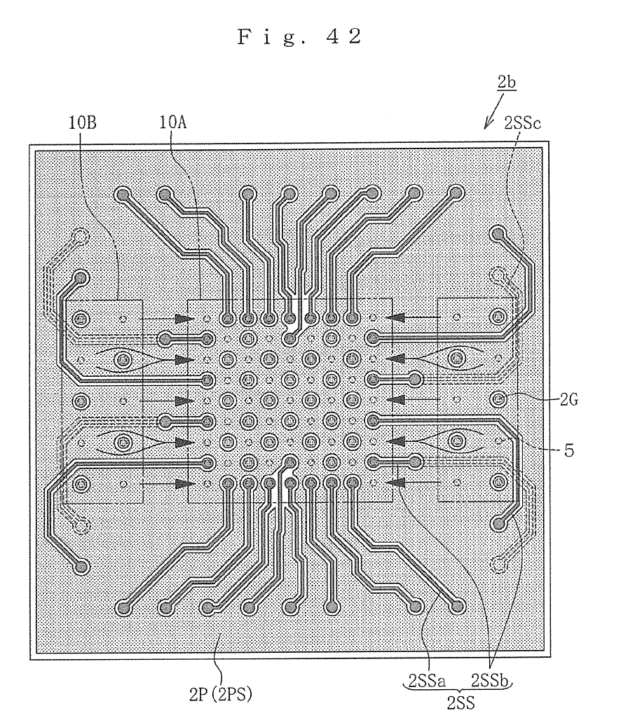

The strip-shaped conductors 2SS for signal in the build-up conductor 2b illustrated in FIG. 42 include the strip-shaped conductor 2SSa extending from the area below the semiconductor-element mount portion 10A to the outer peripheral portion of the insulating substrate 1 without passing through the area below the intermediate portion between the semiconductor-element mount portion 10A and the constant-voltage-regulator mount portion 10B; and the strip-shaped conductor 2SSb extending from the area below the semiconductor-element mount portion 10A to the area below the intermediate portion between the semiconductor-element mount portion 10A and the constant-voltage-regulator mount portion 10B.

The strip-shaped conductors 2SS are electrically connected to the semiconductor-element connection pads 6S for signal via the via holes 5 in the upper layer in the area below the semiconductor-element mount portion 10A. Also, the strip-shaped conductors 2SS are electrically connected to the external connection pad 8S for signal in the outer peripheral portion of the insulating substrate 1 via the through holes 4 and the via holes 5 in the lower layer. Alternatively, the strip-shaped conductors 2SS are electrically connected to the strip-shaped conductor 2SSc of the build-up conductor 2e in the area below the intermediate portion between the semiconductor-element mount portion 10A and the constant-voltage-regulator mount portion 10B.

The strip-shaped conductor 2SSb extending in the area below the constant-voltage-regulator mount portion 10B extends in the arrangement direction of the semiconductor-element mount portion 10A and the constant-voltage-regulator mount portion 10B, and further extends to the area above the external connection pad 8 through the outer-periphery side with respect to the via holes 5 connected to the constant-voltage-regulator connection pad 7 in the insulating substrate 1.

The strip-shaped conductor 2SSb extending to the area below the intermediate portion between the semiconductor-element mount portion 10A and the constant-voltage-regulator mount portion 10B extends in the arrangement direction of the semiconductor-element mount portion 10A and the constant-voltage-regulator mount portion 10B. The strip-shaped conductor 2SSb is connected to the strip-shaped conductor 2SSc in the build-up conductor 2e. The strip-shaped conductor 2SSc extends to the area above the external connection pad 8 through the outer-periphery side with respect to the via holes 5 connected to the constant-voltage-regulator connection pad 7 in the insulating substrate 1.

Hence, in the respective examples illustrated in FIGS. 39 to 42, nothing significantly blocks current supply from the area below the semiconductor-element mount portion 10A to the area below the constant-voltage-regulator mount portion 10B. Accordingly, the current for applying the power supply potential to the semiconductor element S via the solid conductor 2PS for power supply in the build-up conductor 2b can be properly supplied from the constant-voltage regulator V.

The present disclosure is not limited to the above-described embodiments, and may be modified in various ways within the scope of the idea of the present disclosure. For example, the solid conductor 2GS for grounding may be exchanged with the solid conductor 2PS for power supply in any of the above-described embodiments. Further, the numbers of layers of the build-up insulating layers and the build-up conductors are not limited to the above-described numbers of layers, and may be desirably determined.

1. A wiring board, comprising:
an insulating substrate in which a plurality of build-up insulating layers comprising a plurality of via holes is stacked on upper and lower surfaces of a core insulating layer comprising a plurality of through holes, the insulating substrate comprising a semiconductor-element mount portion at a center portion of an upper surface of the insulating substrate, a constant-voltage-regulator mount portion at an outer peripheral portion of the upper surface of the insulating substrate, and an external connection surface at a lower surface of the insulating substrate; and
a wiring conductor applied on the upper and lower surfaces of the core insulating layer, in the through holes, on surfaces of the build-up insulating layers, and in the via holes,
wherein the wiring conductor comprises
a plurality of semiconductor-element connection pads for signal, for grounding, and for power supply in the semiconductor-element mount portion,
a plurality of constant-voltage-regulator connection pads for grounding and for power supply in the constant-voltage-regulator mount portion,
a plurality of external connection pads for signal, for grounding, and for power supply in the external connection surface,
a plurality of wiring conductors for signal connected to the semiconductor-element connection pad for signal in an area below the semiconductor-element mount portion, connected to the external connection pad for signal in an outer peripheral portion of the insulating substrate, and extending in the insulating substrate from the area below the semiconductor-element mount portion to the outer peripheral portion of the insulating substrate,
a plurality of solid conductors for grounding connected to the semiconductor-element connection pad for grounding in the area below the semiconductor-element mount portion, connected to the constant-voltage-regulator connection pad for grounding in an area below the constant-voltage-regulator mount portion, connected to the external connection pad for grounding in the area below the semiconductor-element mount portion and the area below the constant-voltage-regulator mount portion, and extending on surfaces of a plurality of the build-up insulating layers at an upper-surface side and a lower-surface side of the core insulating layer from the area below the semiconductor-element mount portion to the area below the constant-voltage-regulator mount portion, and
a plurality of solid conductors for power supply connected to the semiconductor-element connection pad for power supply in the area below the semiconductor-element mount portion, connected to the constant-voltage-regulator connection pad for power supply in the area below the constant-voltage-regulator mount portion, connected to the external connection pad for power supply in the area below the semiconductor-element mount portion and the area below the constant-voltage-regulator mount portion, and extending on surfaces of a plurality of the build-up insulating layers at the upper-surface side and the lower-surface side of the core insulating layer from the area below the semiconductor-element mount portion to the area below the constant-voltage-regulator mount portion, and
wherein the wiring conductors for signal extend on the surface of the build-up insulating layer, on which the solid conductor for grounding or the solid conductor for power supply extends, to the outer peripheral portion of the insulating substrate without passing through an area below an intermediate portion between the semiconductor-element mount portion and the constant-voltage-regulator mount portion.

2. A wiring board, comprising:
an insulating substrate in which a plurality of build-up insulating layers comprising a plurality of via holes is stacked on upper and lower surfaces of a core insulating layer comprising a plurality of through holes, the insulating substrate comprising a semiconductor-element mount portion at a center portion of an upper surface of the insulating substrate, a constant-voltage-regulator mount portion at an outer peripheral portion of the upper surface of the insulating substrate, and an external connection surface at a lower surface of the insulating substrate; and
a wiring conductor applied on the upper and lower surfaces of the core insulating layer, in the through holes, on surfaces of the build-up insulating layers, and in the via holes,
wherein the wiring conductor comprises
a plurality of semiconductor-element connection pads for signal, for grounding, and for power supply in the semiconductor-element mount portion,
a plurality of constant-voltage-regulator connection pads for grounding and for power supply in the constant-voltage-regulator mount portion,
a plurality of external connection pads for signal, for grounding, and for power supply in the external connection surface,
a plurality of wiring conductors for signal connected to the semiconductor-element connection pad for signal in an area below the semiconductor-element mount portion, connected to the external connection pad for signal in an outer peripheral portion of the insulating substrate, and extending in the insulating substrate from the area below the semiconductor-element mount portion to the outer peripheral portion of the insulating substrate, a portion of the wiring conductors for signal passing through an area below an intermediate portion between the semiconductor-element mount portion and the constant-voltage-regulator mount portion and extending to the outer peripheral portion of the insulating substrate,
a plurality of solid conductors for grounding connected to the semiconductor-element connection pad for grounding in the area below the semiconductor-element mount portion, connected to the constant-voltage-regulator connection pad for grounding in an area below the constant-voltage-regulator mount portion, connected to the external connection pad for grounding in the area below the semiconductor-element mount portion and the area below the constant-voltage-regulator mount portion, and extending on surfaces of a plurality of the build-up insulating layers at an upper-surface side and a lower-surface side of the core insulating layer from the area below the semiconductor-element mount portion to the area below the constant-voltage-regulator mount portion, and
a plurality of solid conductors for power supply connected to the semiconductor-element connection pad for power supply in the area below the semiconductor-element mount portion, connected to the constant-voltage-regulator connection pad for power supply in the area below the constant-voltage-regulator mount portion, connected to the external connection pad for power supply in the area below the semiconductor-element mount portion and the area below the constant-voltage-regulator mount portion, and extending on surfaces of a plurality of the build-up insulating layers at the upper-surface side and the lower-surface side of the core insulating layer from the area below the semiconductor-element mount portion to the area below the constant-voltage-regulator mount portion, and
wherein the portion of the wiring conductors for signal comprises an upper-surface-side strip-shaped conductor extending on the surface of the build-up insulating layer, on which the solid conductor for grounding or the solid conductor for power supply extends, at the upper-surface side of the core insulating layer from the area below the semiconductor-element mount portion to the area below the intermediate portion, and a lower-surface-side strip-shaped conductor extending on the surface of the build-up insulating layer, on which the solid conductor for grounding or the solid conductor for power supply extends, at the lower-surface side of the core insulating layer from the area below the intermediate portion to the outer peripheral portion of the insulating substrate, and the upper-surface-side strip-shaped conductor is electrically connected to the lower-surface-side strip-shaped conductor via the through hole in the area below the intermediate portion.

3. A wiring board, comprising:
an insulating substrate in which a plurality of build-up insulating layers comprising a plurality of via holes is stacked on upper and lower surfaces of a core insulating layer comprising a plurality of through holes, the insulating substrate comprising a semiconductor-element mount portion at a center portion of an upper surface of the insulating substrate, a constant-voltage-regulator mount portion at an outer peripheral portion of the upper surface of the insulating substrate, and an external connection surface at a lower surface of the insulating substrate; and
a wiring conductor applied on the upper and lower surfaces of the core insulating layer, in the through holes, on surfaces of the build-up insulating layers, and in the via holes,
wherein the wiring conductor comprises
a plurality of semiconductor-element connection pads for signal, for grounding, and for power supply in the semiconductor-element mount portion,
a plurality of constant-voltage-regulator connection pads for grounding and for power supply in the constant-voltage-regulator mount portion,
a plurality of external connection pads for signal, for grounding, and for power supply in the external connection surface,
a plurality of wiring conductors for signal connected to the semiconductor-element connection pad for signal in an area below the semiconductor-element mount portion, connected to the external connection pad for signal in an outer peripheral portion of the insulating substrate, and extending in the insulating substrate from the area below the semiconductor-element mount portion to the outer peripheral portion of the insulating substrate, a portion of the wiring conductors for signal extending to an area below the constant-voltage-regulator mount portion,
a plurality of solid conductors for grounding connected to the semiconductor-element connection pad for grounding in the area below the semiconductor-element mount portion, connected to the constant-voltage-regulator connection pad for grounding in the area below the constant-voltage-regulator mount portion, connected to the external connection pad for grounding in the area below the semiconductor-element mount portion and the area below the constant-voltage-regulator mount portion, and extending on surfaces of a plurality of the build-up insulating layers at an upper-surface side and a lower-surface side of the core insulating layer from the area below the semiconductor-element mount portion to the area below the constant-voltage-regulator mount portion, and
a plurality of solid conductors for power supply connected to the semiconductor-element connection pad for power supply in the area below the semiconductor-element mount portion, connected to the constant-voltage-regulator connection pad for power supply in the area below the constant-voltage-regulator mount portion, connected to the external connection pad for power supply in the area below the semiconductor-element mount portion and the area below the constant-voltage-regulator mount portion, and extending on surfaces of a plurality of the build-up insulating layers at the upper-surface side and the lower-surface side of the core insulating layer from the area below the semiconductor-element mount portion to the area below the constant-voltage-regulator mount portion, and
wherein a plurality of the external connection pads for grounding and for power supply of the external connection pads is at the external connection surface in the area below the semiconductor-element mount portion, a part of the portion of the wiring conductors for signal extending to the area below the constant-voltage-regulator mount portion is on a surface of the build-up insulating layer at the lower-surface side of the core insulating layer, the constant-voltage-regulator connection pads for grounding and for power supply are electrically connected in a thermally conductive manner to the solid conductors for grounding and for power supply at the upper-surface side of the core insulating layer via the plurality of via holes in the build-up insulating layer at the upper-surface side in an area below the respective constant-voltage-regulator connection pads and an area below a space between the constant-voltage-regulator connection pads, and the solid conductors for grounding and for power supply at the upper-surface side of the core insulating layer, the solid conductors for grounding and for power supply at the lower-surface side of the core insulating layer, and the external connection pads for grounding and for power supply in the area below the semiconductor-element mount portion are electrically connected in a thermally conductive manner via the plurality of through holes in the core insulating layer and the plurality of via holes in the build-up insulating layers at the lower-surface side in the area below the semiconductor-element mount portion.

4. A wiring board, comprising:
an insulating substrate in which a plurality of build-up insulating layers comprising a plurality of via holes is stacked on upper and lower surfaces of a core insulating layer comprising a plurality of through holes, the insulating substrate comprising a semiconductor-element mount portion at a center portion of an upper surface of the insulating substrate, a constant-voltage-regulator mount portion at an outer peripheral portion of the upper surface of the insulating substrate, and an external connection surface at a lower surface of the insulating substrate; and
a wiring conductor applied on the upper and lower surfaces of the core insulating layer, in the through holes, on surfaces of the build-up insulating layers, and in the via holes,
wherein the wiring conductor comprises
a plurality of semiconductor-element connection pads for signal, for grounding, and for power supply in the semiconductor-element mount portion,
a plurality of constant-voltage-regulator connection pads for grounding and for power supply in the constant-voltage-regulator mount portion,
a plurality of external connection pads for signal, for grounding, and for power supply in the external connection surface,
a plurality of wiring conductors for signal connected to the semiconductor-element connection pad for signal in an area below the semiconductor-element mount portion, connected to the external connection pad for signal in an outer peripheral portion of the insulating substrate, and extending in the insulating substrate from the area below the semiconductor-element mount portion to the outer peripheral portion of the insulating substrate,
a plurality of solid conductors for grounding connected to the semiconductor-element connection pad for grounding in the area below the semiconductor-element mount portion, connected to the constant-voltage-regulator connection pad for grounding in the area below the constant-voltage-regulator mount portion, connected to the external connection pad for grounding in the area below the semiconductor-element mount portion and the area below the constant-voltage-regulator mount portion, and extending on surfaces of a plurality of the build-up insulating layers at an upper-surface side and a lower-surface side of the core insulating layer from the area below the semiconductor-element mount portion to the area below the constant-voltage-regulator mount portion, and
a plurality of solid conductors for power supply connected to the semiconductor-element connection pad for power supply in the area below the semiconductor-element mount portion, connected to the constant-voltage-regulator connection pad for power supply in the area below the constant-voltage-regulator mount portion, connected to the external connection pad for power supply in the area below the semiconductor-element mount portion and the area below the constant-voltage-regulator mount portion, and extending on surfaces of a plurality of the build-up insulating layers at the upper-surface side and the lower-surface side of the core insulating layer from the area below the semiconductor-element mount portion to the area below the constant-voltage-regulator mount portion, and
wherein the external connection pads for grounding and for power supply of the external connection pads are disposed at the external connection surface in the area below the constant-voltage-regulator mount portion, and the external connection pads for grounding and for power supply in the area below the constant-voltage-regulator mount portion are electrically connected in a thermally conductive manner to the constant-voltage-regulator connection pads for grounding and for power supply via a plurality of via holes and a plurality of through holes disposed from the upper surface to the lower surface of the insulating substrate in the area below the constant-voltage-regulator mount portion.

5. A wiring board, comprising:
an insulating substrate in which a plurality of build-up insulating layers comprising a plurality of via holes is stacked on upper and lower surfaces of a core insulating layer comprising a plurality of through holes, the insulating substrate comprising a semiconductor-element mount portion at a center portion of an upper surface of the insulating substrate, a constant-voltage-regulator mount portion at an outer peripheral portion of the upper surface of the insulating substrate, and an external connection surface at a lower surface of the insulating substrate; and
a wiring conductor applied on the upper and lower surfaces of the core insulating layer, in the through holes, on surfaces of the build-up insulating layers, and in the via holes,
wherein the wiring conductor comprises
a plurality of semiconductor-element connection pads for signal, for grounding, and for power supply in the semiconductor-element mount portion,
a plurality of constant-voltage-regulator connection pads for grounding and for power supply in the constant-voltage-regulator mount portion,
a plurality of external connection pads for signal, for grounding, and for power supply in the external connection surface,
a plurality of wiring conductors for signal connected to the semiconductor-element connection pad for signal via the via holes in an area below the semiconductor-element mount portion, connected to the external connection pad for signal via the via holes in an outer peripheral portion of the insulating substrate, and extending in the insulating substrate from the area below the semiconductor-element mount portion to the outer peripheral portion of the insulating substrate, a portion of the wiring conductors for signal passing through an area below an intermediate portion between the semiconductor-element mount portion and the constant-voltage-regulator mount portion,
a plurality of solid conductors for grounding connected to the semiconductor-element connection pad for grounding via the via holes in the area below the semiconductor-element mount portion, connected to the constant-voltage-regulator connection pad for grounding via the via holes in the area below the constant-voltage-regulator mount portion, connected to the external connection pad for grounding via the via holes in the area below the semiconductor-element mount portion and the area below the constant-voltage-regulator mount portion, and extending on surfaces of a plurality of the build-up insulating layers at an upper-surface side and a lower-surface side of the core insulating layer from the area below the semiconductor-element mount portion to the area below the constant-voltage-regulator mount portion, and
a plurality of solid conductors for power supply connected to the semiconductor-element connection pad for power supply via the via holes in the area below the semiconductor-element mount portion, connected to the constant-voltage-regulator connection pad for power supply via the via holes in the area below the constant-voltage-regulator mount portion, connected to the external connection pad for power supply via the via holes in the area below the semiconductor-element mount portion and the area below the constant-voltage-regulator mount portion, and extending on surfaces of a plurality of the build-up insulating layers at the upper-surface side and the lower-surface side of the core insulating layer from the area below the semiconductor-element mount portion to the area below the constant-voltage-regulator mount portion, and
wherein the portion of the wiring conductors for signal comprises a strip-shaped conductor extending on the surface of the build-up insulating layer, on which the solid conductor for grounding or the solid conductor for power supply extends, in an arrangement direction of the semiconductor-element mount portion and the constant-voltage-regulator mount portion along a wiring path extending from the area below the semiconductor-element mount portion to the area below the constant-voltage-regulator mount portion, and the strip-shaped conductor extends to an area above the external connection pads through an outer-periphery side of the insulating substrate with respect to the via holes connected to the constant-voltage-regulator connection pads.

6. An electronic device wherein a semiconductor element is mounted on the semiconductor-element mount portion and a constant-voltage regulator is mounted on the constant-voltage-regulator mount portion of the wiring board according to claim 1.

7. An electronic device wherein a semiconductor element is mounted on the semiconductor-element mount portion and a constant-voltage regulator is mounted on the constant-voltage-regulator mount portion of the wiring board according to claim 2.

8. An electronic device wherein a semiconductor element is mounted on the semiconductor-element mount portion and a constant-voltage regulator is mounted on the constant-voltage-regulator mount portion of the wiring board according to claim 3.

9. An electronic device wherein a semiconductor element is mounted on the semiconductor-element mount portion and a constant-voltage regulator is mounted on the constant-voltage-regulator mount portion of the wiring board according to claim 4.

10. An electronic device wherein a semiconductor element is mounted on the semiconductor-element mount portion and a constant-voltage regulator is mounted on the constant-voltage-regulator mount portion of the wiring board according to claim 5.
